(19) United States
(12) Patent Application Publication
(10) Pub. No.: US 2026/0032924 A1
(43) Pub. Date: Jan. 29, 2026

(54) NON-VOLATILE MEMORY DEVICE

(71) Applicant: SAMSUNG ELECTRONICS CO., LTD., Suwon-si (KR)

(72) Inventors: Yongsung Cho, Suwon-si (KR); Insu Kim, Suwon-si (KR); Takuya Futatsuyama, Suwon-si (KR); Dongha Shin, Suwon-si (KR); Beakhyung Cho, Suwon-si (KR)

(21) Appl. No.: 19/199,007

(22) Filed: May 5, 2025

(30) Foreign Application Priority Data
Jul. 29, 2024 (KR) 10-2024-0100190

(51) Int. Cl. H10B 80/00; G11C 16/04; G11C 16/24; H01L 23/00; H01L 25/065; H01L 25/18

(52) U.S. Cl. CPC H10B 80/00; G11C 16/0483; G11C 16/24; H01L 24/08; H01L 25/0657; H01L 25/18; H01L 2224/08145; H01L 2924/1431; H01L 2924/14511

(57) ABSTRACT

A non-volatile memory device is provided, including a first bit line, a second bit line, a first page buffer including a first erase transistor connected to the first bit line via a first bonding pad, and a second page buffer including a second erase transistor connected to the second bit line via a second bonding pad, and a plurality of bonding pads including a first bonding pad and a second bonding pad. The first erase transistor is driven based on a first erase control signal and is connected between the first bit line and the first erase voltage line. The second erase transistor is driven based on a first erase control signal and is connected between the second bit line and the second erase voltage line different from the first erase voltage line. The first bonding pad and the second bonding pad are disposed adjacent to each other.

### CROSS-REFERENCE TO RELATED APPLICATION

This application claims priority to Korean Patent Application No. 10-2024-0100190, filed in the Korean Intellectual Property Office on Jul. 29, 2024, the entire contents of which are hereby incorporated by reference.

### BACKGROUND

Three-dimensional (3D) non-volatile memory devices, in which a memory cell array and a peripheral circuit are disposed in a vertical direction, have been developed for high-capacity, small non-volatile memory devices.

In bonding vertical NAND (BVNAND) flash memories, misalignment may occur between bonding pads when semiconductor layers are bonded to each other. If misalignment occurs between bonding pads, the constituent materials of the bonding pad may be migrated. Therefore, the circuits in the non-volatile memory device are desired to be designed to test for potential misalignment of bonding pads.

### SUMMARY

In order to solve one or more problems (e.g., the problems described above and/or other problems not explicitly described herein), the present disclosure relates to a non-volatile memory device and a method for manufacturing the same.

The objects to be achieved by the present disclosure are not limited to the above, and other objects not explicitly described herein may be clearly understood by those skilled in the art from the description of the present disclosure.

A non-volatile memory device may include a plurality of bit lines including a first bit line and a second bit line, a page buffer circuit including a first page buffer including a first erase transistor connected to the first bit line via a first bonding pad, and a second page buffer including a second erase transistor connected to the second bit line via a second bonding pad, and a plurality of bonding pads including a first bonding pad and a second bonding pad, in which the page buffer circuit may be connected to the plurality of bit lines via the plurality of bonding pads. The first erase transistor may be driven based on a first erase control signal, and the first erase transistor is connected between the first bit line and the first erase voltage line, the second erase transistor may be driven based on the first erase control signal, and the second erase transistor is connected between the second bit line and the second erase voltage line different from the first erase voltage line, and the first bonding pad and the second bonding pad may be disposed adjacent to each other.

A non-volatile memory device may include a plurality of bit lines including a first bit line and a second bit line, a page buffer circuit including a first page buffer including a first erase transistor connected to the first bit line via a first bonding pad, and a second page buffer including a second erase transistor connected to the second bit line via a second bonding pad, and a plurality of bonding pads including a first bonding pad and a second bonding pad, in which the page buffer circuit may be connected to the plurality of bit lines via the plurality of bonding pads. The first erase transistor may be driven based on a first erase control signal, and the first erase transistor is connected between the first bit line and the first erase voltage line, the second erase transistor may be driven based on the first erase control signal, and the second erase transistor is connected between the second bit line and the second erase voltage line different from the first erase voltage line, the first bonding pad and the second bonding pad may be disposed adjacent to each other, in response to activation of a mode in which a stress test is performed on the plurality of bonding pads, a positive voltage may be applied to any one of the first erase voltage line and the second erase voltage line, and a ground voltage may be applied to the other one of the first erase voltage line and the second erase voltage line. The plurality of bonding pads may include a plurality of upper bonding pads and a plurality of lower bonding pads, the plurality of bit lines and the plurality of upper bonding pads may be formed on a first semiconductor layer, the plurality of lower bonding pads and the page buffer circuit may be formed on the second semiconductor layer, and the first semiconductor layer and the second semiconductor layer may be coupled by bonding the plurality of upper bonding pads and the plurality of lower bonding pads. The first page buffer may include a high voltage region including a first erase transistor and a bit line select transistor, and a low voltage region spaced apart from the high voltage regions in the first direction and including a transistor connected to the first erase transistors via the bit line select transistor.

A non-volatile memory device may include a plurality of bit lines including a first bit line and a second bit line, and extending in a first direction, respectively, a plurality of bonding pads, and a page buffer circuit having a multi-stage structure including a plurality of stages, in which the page buffer may include a plurality of page buffers, and may be connected to the plurality of bit lines via the plurality of bonding pads. A first stage of the multi-stage structure may include a plurality of first high voltage regions including a plurality of first erase transistors connected to a first erase voltage line, a second stage of the multi-stage structure may include a plurality of second high voltage regions including a plurality of second erase transistors connected to a second erase voltage line different from the first erase voltage line, a first transistor of the plurality of first erase transistors may be connected between the first bit line and the first erase voltage line, a second transistor of the plurality of second erase transistors may be connected between the second bit line and the second erase voltage line, the first bit line may be connected to the first transistor through a first bonding pad of the plurality of bonding pads, the second bit line may be connected to the second transistor through a second bonding pad of the plurality of bonding pads, the first bonding pad and the second bonding pad may be spaced apart and adjacent to each other in the first direction, and the second bonding pad and the plurality of second high voltage regions may be spaced apart from each other in a second direction intersecting the first direction.

According to various aspects of the present disclosure, by connecting different erase voltage lines to each of the erase transistors that are connected to adjacent bonding pads and activated by the same gate signal, it is possible to implement a page buffer circuit that is capable of performing both the stress test on the bit lines and the stress test between the bonding pads.

According to various aspects of the present disclosure, by placing a bonding pad connected to the erase voltage line of any one of the erase transistors connected with different erase voltage lines adjacent to the bonding pad connected to a different erase voltage line, it is possible to implement a page buffer circuit that is capable of performing both the stress test on the bit lines and the stress test between the bonding pads.

Various and beneficial advantages and effects of the present disclosure are not limited to those described above, and can be more easily understood in the course of describing specific aspects of the present disclosure.

### BRIEF DESCRIPTION OF THE DRAWINGS

The above and other objects, features and advantages of the present disclosure will become more apparent to those of ordinary skill in the art by describing in detail exemplary implementations thereof with reference to the accompanying drawings, in which:

FIG. 1 is a block diagram illustrating a memory device;

FIG. 2 is a circuit diagram illustrating a memory block;

FIG. 3 is a diagram schematically illustrating a structure of a memory device;

FIG. 4 is a diagram illustrating a memory cell array and a page buffer circuit;

FIG. 5 is a cross-sectional view of a non-volatile memory device;

FIG. 6 is a cross-sectional view illustrating in detail a region including an upper bonding pad and a lower bonding pad of FIG. 5;

FIG. 7 is a plan view illustrating a page buffer circuit;

FIG. 8A is a plan view illustrating the page buffer circuit of FIG. 7 in more detail;

FIG. 8B is a plan view illustrating a modification of the page buffer circuit of FIG. 8A;

FIG. 9A is a plan view illustrating in detail a high voltage region of a first end of FIG. 8A;

FIG. 9B is a plan view illustrating in detail a high voltage region of a second end of FIG. 8A;

FIG. 9C is a diagram illustrating voltages applied to a plurality of bonding pads during a stress test using the high voltage regions of FIGS. 9A and 9B;

FIG. 10A is a plan view illustrating in detail the high voltage region of the first end of FIG. 8A according to another aspect;

FIG. 10B is a plan view illustrating in detail the high voltage region of the second end of FIG. 8A;

FIG. 10C is a diagram illustrating voltages applied to a plurality of bonding pads during a stress test using the high voltage regions of FIGS. 10A and 10B;

FIG. 11 is a plan view illustrating a page buffer circuit;

FIG. 12 is a plan view illustrating in detail the page buffer circuit of FIG. 11;

FIG. 13 is a plan view illustrating in detail the high voltage regions of the first and second stages of FIG. 12;

FIGS. 14A and 14B are diagrams illustrating in detail a connection structure of bit lines of FIG. 13;

FIG. 15 is a diagram illustrating voltages applied to a plurality of bonding pads according to the high voltage regions of FIG. 13; and

FIG. 16 is a block diagram illustrating an electronic system including a semiconductor device according to some aspects.

### DETAILED DESCRIPTION

In the present disclosure, when A and B are “adjacent” to each other, it may mean that no other configuration (e.g., another configuration of the same kind as A and B) is disposed or positioned between A and B. For example, if first and second bit lines are adjacent to each other in a particular direction, another bit line may not be disposed or positioned between the first and second bit lines in that direction.

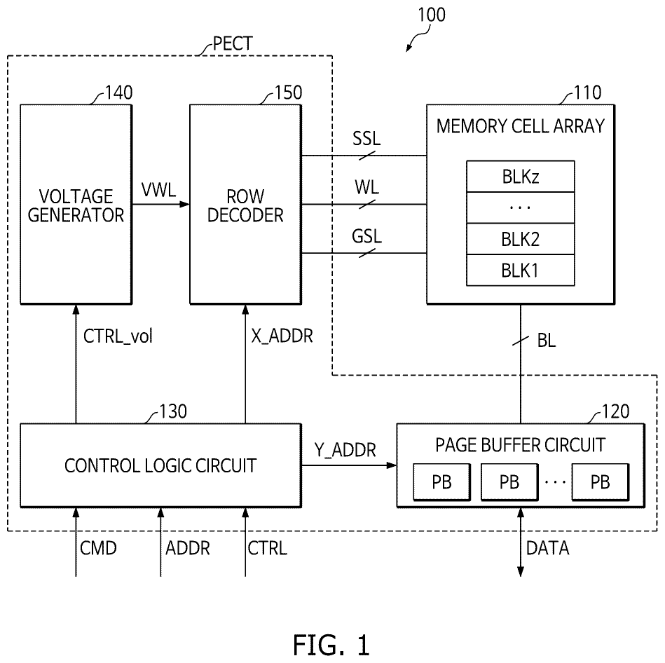

FIG. 1 is a diagram illustrating a memory device 100.

Referring to FIG. 1, the memory device 100 may include a memory cell array 110 and a peripheral circuit PECT, and the peripheral circuit PECT may include a page buffer circuit 120, a control logic circuit 130, a voltage generator 140, and a row decoder 150. The peripheral circuit PECT may further include a data input and output circuit, an input and output interface, etc. In addition, the peripheral circuit PECT may further include a temperature sensor, a command decoder, an address decoder, etc. Throughout the description, the memory device 100 may refer to a non-volatile memory device.

The memory cell array 110 may include a plurality of memory blocks BLK1 to BLKz (where, z is a natural number), and each of the plurality of memory blocks BLK1 to BLKz may include a plurality of memory cells. The memory cell array 110 may be connected to the page buffer circuit 120 via bit lines BL, and may be connected to the row decoder 150 through word lines WL, string select lines SSL, and ground select lines GSL. For example, the memory cells may be flash memory cells. Hereinafter, aspects of the present disclosure will be described with reference to an example in which the memory cells are NAND flash memory cells. However, aspects are not limited thereto, and in some aspects, the memory cells may be resistive memory cells such as resistive RAM (ReRAM), phase change RAM (PRAM), or magnetic RAM (MRAM).

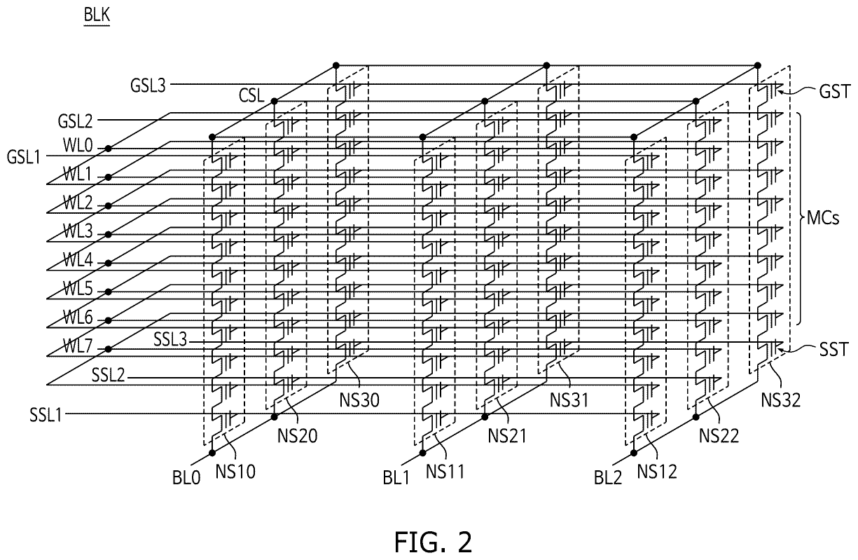

The memory cell array 110 may include a 3D memory cell array, and the 3D memory cell array may include a plurality of NAND strings. Each NAND string may include memory cells respectively connected to word lines vertically stacked on the substrate, which will be described in detail with reference to FIG. 2. Aspects are not limited thereto, and in some aspects, the memory cell array 110 may include a 2D memory cell array, and the 2D memory cell array may include a plurality of NAND strings disposed along row and column directions.

The page buffer circuit 120 may include a plurality of page buffers PB. Each of the plurality of page buffers PB may be connected to the memory cells of the memory cell array 110 through a corresponding bit line. The page buffer circuit 120 may select at least one bit line of the bit lines BL under the control of the control logic circuit 130. For example, the page buffer circuit 120 may select some of the bit lines BL in response to a column address Y_ADDR received from the control logic circuit 130. Each of the plurality of page buffers PB may operate as a write driver or a sense amplifier. For example, in a program operation, each of the plurality of page buffers PB may apply a voltage corresponding to the data DATA to be programmed to the bit line and store the data DATA in the memory cell. For example, in a program verification or read operation, each of the plurality of page buffers PB may sense a current or voltage through the bit line to sense the programmed data DATA.

The control logic circuit 130 may output various control signals, such as a voltage control signal CTRL_vol, a row address X_ADDR, and a column address Y_ADDR, for programming data into the memory cell array 110, reading data from the memory cell array 110, or erasing data stored in the memory cell array 110, based on a command CMD, an address ADDR, and a control signal CTRL. Thus, the control logic circuit 130 may control various operations in the memory device 100 as a whole. For example, the control logic circuit 130 may receive the command CMD, the address ADDR, and the control signal CTRL from the memory controller.

The voltage generator 140 may generate various types of voltages for performing program, read, and erase operations on the memory cell array 110 based on the voltage control signal CTRL_vol. Specifically, the voltage generator 140 may generate a word line voltage VWL such as a program voltage, a read voltage, a pass voltage, an erase verification voltage, or a program verification voltage. In addition, the voltage generator 140 may further generate a string select line voltage and a ground select line voltage based on the voltage control signal CTRL_vol.

In response to the row address X_ADDR received from the control logic circuit 130, the row decoder 150 may select one of the plurality of memory blocks BLK1 to BLKz, select one of the word lines WL of the selected memory block, and select one of the string select lines SSL. For example, in the program operation, the row decoder 150 may apply a program voltage and a program verification voltage to the selected word line, and in the read operation, the row decoder 150 may apply a read voltage to the selected word line.

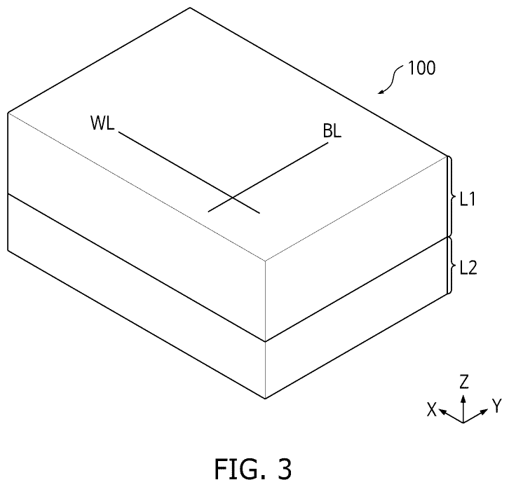

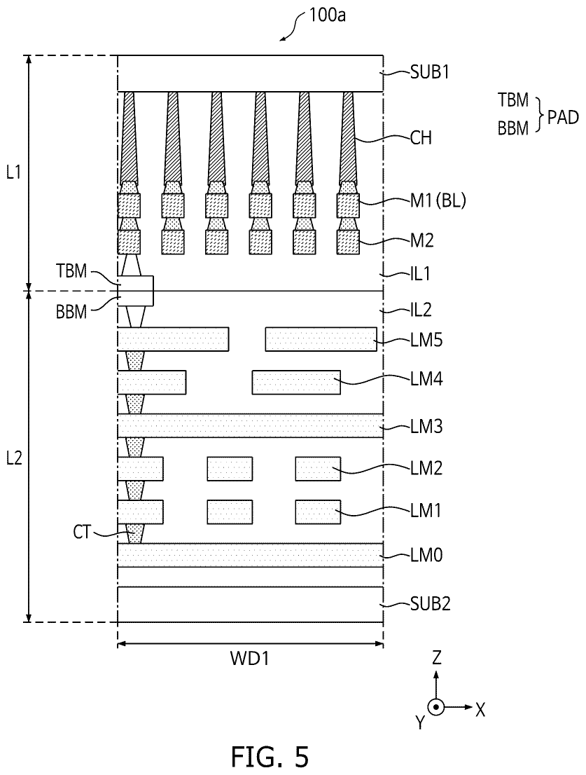

The memory cell array 110 may be disposed in a first semiconductor layer (e.g., L1 of FIGS. 3 and 5), and the peripheral circuit PECT may be disposed in the second semiconductor layer (e.g., L2 of FIGS. 3 and 5). In this case, at least a portion of the peripheral circuit PECT may overlap the memory cell array 110 in a vertical direction.

FIG. 2 is a circuit diagram illustrating a memory block BLK.

Referring to FIG. 2, the memory block BLK may correspond to one of the plurality of memory blocks BLK1 to BLKz in FIG. 1. The memory block BLK includes NAND strings NS10 to NS32, and each NAND string (e.g., NS10) may include a string select transistor SST, a plurality of memory cells MCs, and a ground select transistor GST connected to each other in series. The transistors SST and GST and the memory cells MCs included in each NAND string may form a vertically stacked structure on the substrate.

The bit lines BL0 to BL2 may extend along a first direction (e.g., along a Y direction of FIG. 3), and the word lines WL0 to WL7 may extend in a second direction (e.g., in an X direction of FIG. 3). The first direction may be referred to as a first horizontal direction, and the second direction may be referred to as a second horizontal direction. The NAND strings NS10, NS20, and NS30 may be positioned between a first bit line BL0 and a common source line CSL, the NAND strings NS11, NS21, and NS31 may be positioned between a second bit line BL1 and the common source line CSL, and the NAND strings NS12, NS22, and NS32 may be positioned between a third bit line BL2 and the common source line CSL.

The string select transistor SST may be connected to corresponding string select lines SSL1 to SSL3. The memory cells MCs may be connected to the corresponding word lines WL0 to WL7, respectively. The ground select transistor GST may be connected to corresponding ground select lines GSL1 to GSL3. The string select transistor SST may be connected to a corresponding bit line, and the ground select transistor GST may be connected to the common source line CSL. The number of NAND strings, the number of word lines, the number of bit lines, the number of ground select lines, and the number of string select lines may be variously changed according to aspects.

FIG. 3 is a diagram schematically illustrating a structure of the memory device 100.

Referring to FIGS. 1 and 3 together, the memory device 100 may include a first semiconductor layer L1 and a second semiconductor layer L2, and the first semiconductor layer L1 may be stacked in a vertical direction Z with respect to the second semiconductor layer L2. Specifically, the second semiconductor layer L2 may be disposed below the first semiconductor layer L1 in the vertical direction Z. The memory cell array 110 may be formed in the first semiconductor layer L1, and the peripheral circuit PECT may be formed in the second semiconductor layer L2. Accordingly, the memory device 100 may have a bonding VNAND (B-VNAND) structure in which the memory cell array 110 is disposed above the peripheral circuit PECT.

In the first semiconductor layer L1, a plurality of bit lines BL may extend in the first direction Y, and a plurality of word lines WL may extend in the second direction X. The second semiconductor layer L2 may include a substrate, and semiconductor devices such as transistors and a pattern for wiring the devices may be formed on the substrate to form the peripheral circuit PECT on the second semiconductor layer L2.

If the memory device 100 has the B-VNAND structure, the peripheral circuit PECT and lower bonding pads may be formed on the second semiconductor layer L2, the memory cell array 110 and upper bonding pads may be formed on the first semiconductor layer L1, and then the upper bonding pads on the first semiconductor layer L1 and the lower bonding pads on the second semiconductor layer L2 may be connected to each other in a bonding manner.

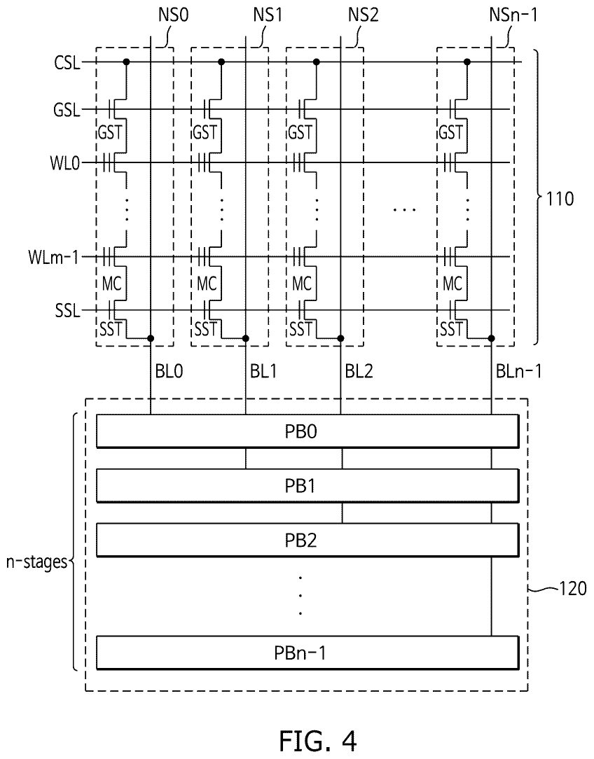

FIG. 4 is a diagram illustrating the memory cell array 110 and the page buffer circuit 120.

Referring to FIG. 4, the memory cell array 110 may include first to n-th NAND strings NS0 to NSn−1. Each of the first to n-th NAND strings NS0 to NSn−1 may include a ground select transistor GST connected to the ground select line GSL, a plurality of memory cells MC connected to a plurality of word lines WL0 to WLm−1, respectively, and a string select transistor SST connected to the string select line SSL. The ground select transistor GST, the plurality of memory cells MC, and the string select transistor SST may be connected in series to each other (where, m and n are natural numbers).

The page buffer circuit 120 may have a multi-stage structure including first to n-th page buffers PB0 to PBn−1. The first page buffer PB0 may be connected to the first NAND string NS0 through the first bit line BL0, and the n-th page buffer PBn−1 may be connected to the n-th NAND string NSn−1 through the n-th bit line BLn−1. “n” is a positive integer. For example, the first to n-th page buffers PB0 to PBn−1 may be disposed in a row along a direction of extension of the first to n-th bit lines BL0 to BLn−1.

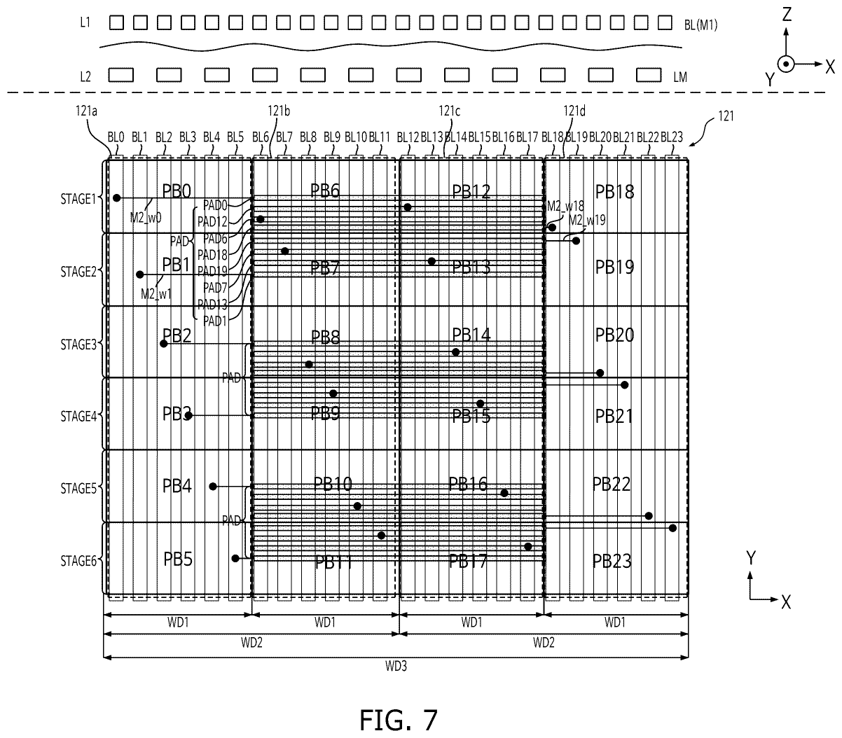

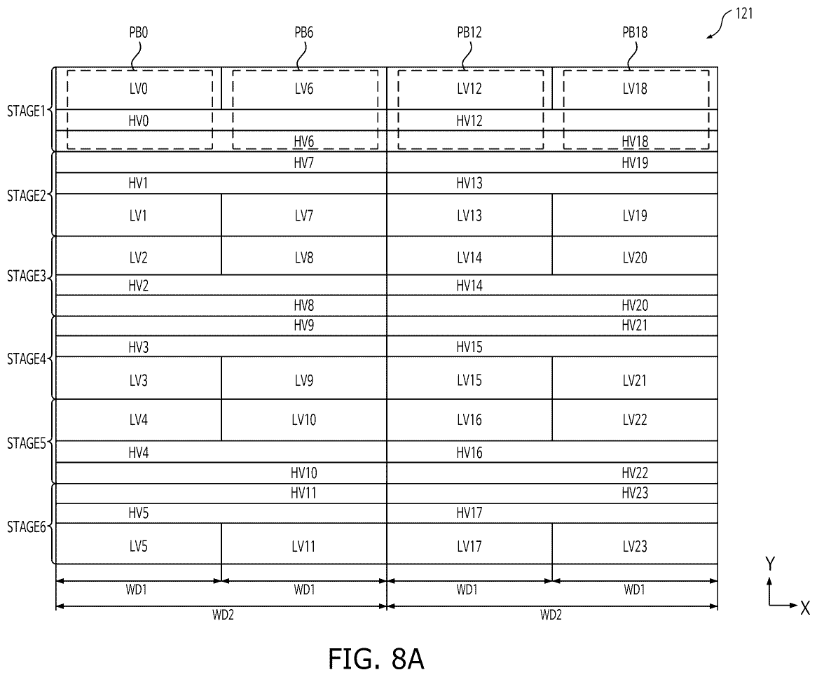

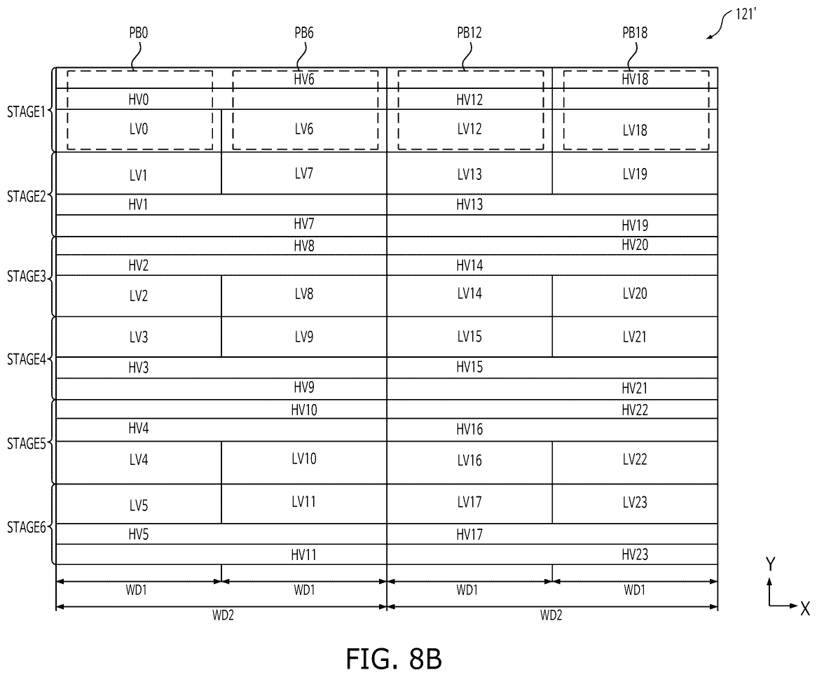

“n” may be 6, and the page buffer circuit 120 may have a six-stage structure in which six stages of page buffers PB0 to PB5 are disposed in a row, which will be described in detail with reference to FIGS. 7, 8A, and 8B.

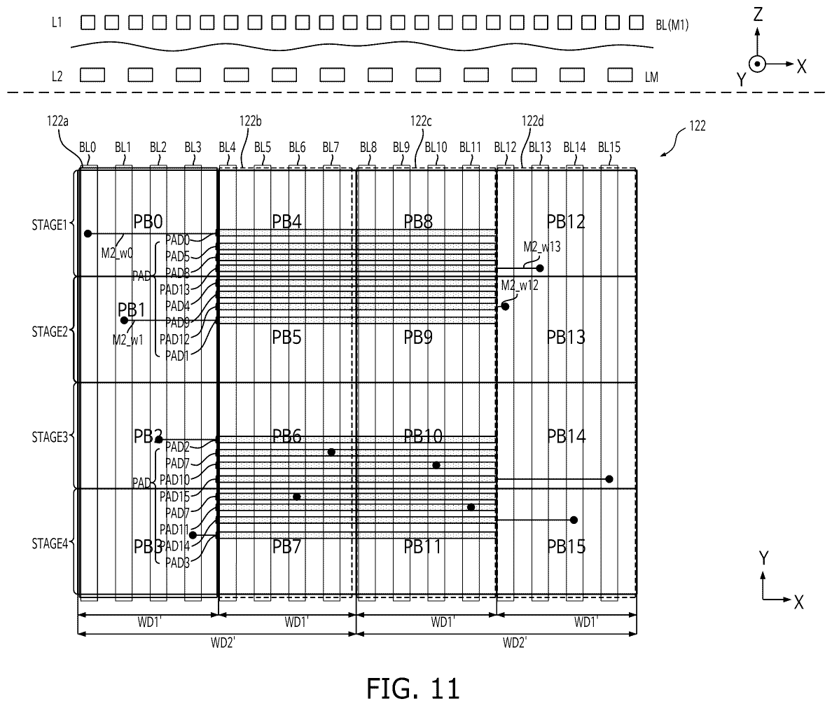

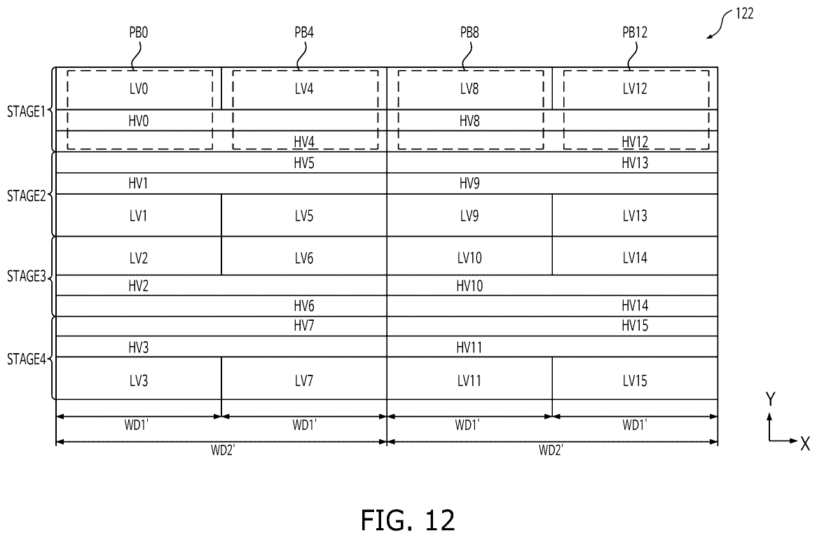

“n” may be 4, and the page buffer circuit 120 may have a four-stage structure in which four stages of page buffers PB0 to PB3 are disposed in a row, which will be described in detail with reference to FIGS. 11 and 12.

FIG. 5 is a cross-sectional view of a non-volatile memory device.

Referring to FIG. 5, the memory device 100a may include the first semiconductor layer L1 and the second semiconductor layer L2 disposed in the vertical direction Z. The first semiconductor layer L1 may include an upper bonding pad TBM, and the second semiconductor layer L2 may include a lower bonding pad BBM. The first and second semiconductor layers L1 and L2 may be coupled to each other by bonding the upper bonding pad TBM and the lower bonding pad BBM. The bonding pad PAD may refer to the upper bonding pad TBM and the lower bonding pad BBM. As described above, the memory device 100a may be implemented as a B-VNAND.

The first semiconductor layer L1 may further include channel structures CH extending from an upper substrate SUB1 in the vertical direction Z, respectively. A first upper metal layer M1 and a second upper metal layer M2 may be disposed on upper portions of the channel structures CH. For example, the first and second upper metal layers M1 and M2 may extend in the first direction Y. For example, the bit lines BL may be implemented as the first upper metal layer M1. The channel structures CH, and the first and second upper metal layers M1 and M2 may be connected to each other through contacts CT. The first semiconductor layer L1 may further include an insulating layer IL1 covering the upper substrate SUB1, the channel structures CH, the first and second upper metal layers M1 and M2, and the upper bonding pad TBM.

The second semiconductor layer L2 may include first to sixth lower metal layers LM0 to LM5 sequentially disposed above a lower substrate SUB2 in the vertical direction Z. The first to sixth lower metal layers LM0 to LM5 may be connected to each other through the contacts CT. The second semiconductor layer L2 may further include an insulating layer IL2 covering the lower substrate SUB2, the first to sixth lower metal layers LM0 to LM5, and the lower bonding pad BBM.

For example, the second, third, fifth and sixth lower metal layers LM1, LM2, LM4, and LM5 may extend in the first direction Y, and the first and fourth lower metal layers LM0 and LM3 may extend in the second direction X. However, aspects are not limited thereto, and the first or fourth lower metal layers LM0 and LM3 may extend in an oblique direction with respect to the first direction Y. For example, in a region corresponding to a first width WD1, the second lower metal layer LM1 may include three metal lines, and the third lower metal layer LM2 may also include three metal lines, but aspects are not limited thereto. For example, in the region corresponding to the first width WD1, the fifth lower metal layer LM4 may include two metal lines, and the sixth lower metal layer LM5 may include two metal lines, but aspects are not limited thereto.

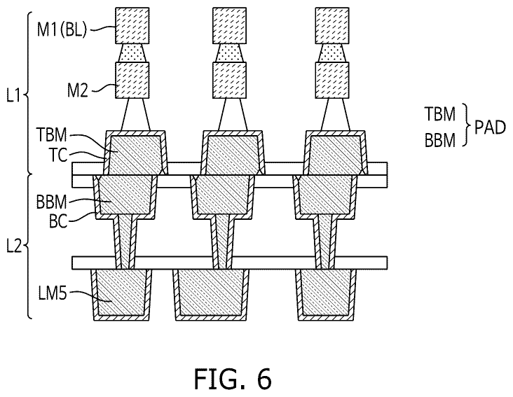

FIG. 6 is a cross-sectional view illustrating in detail a region including the upper bonding pad TBM and the lower bonding pad BBM of FIG. 5. An upper capping TC may be formed in a portion of a surface of the upper bonding pad TBM, and a lower capping BC may be formed in a portion of a surface of the lower bonding pad BBM.

As illustrated in FIG. 6, upon coupling between the first semiconductor layer L1 and the second semiconductor layer L2, the upper bonding pad TBM and the lower bonding pad BBM may be misaligned with each other due to issues in the process. That is, the upper capping TC and the lower capping BC may not be engaged with each other, and at least a portion of the upper bonding pad TBM and the lower bonding pad BBM may be exposed at a boundary surface between the first semiconductor layer L1 and the second semiconductor layer L2. In this case, migration of metal materials (e.g., Cu) included in the upper bonding pad (TBM) and the lower bonding pad (BBM) may occur.

A stress test may be performed on a plurality of bonding pads PAD to determine whether the upper bonding pad TBM and the lower bonding pad BBM are misaligned. The stress test on the plurality of bonding pads PAD may be performed by applying different voltages between adjacent bonding pads to evaluate the electrical durability of the bonding pads and to check the operation in a high voltage situation.

Likewise, a stress test on the plurality of bit lines BL may be performed by applying different voltages between adjacent bit lines of the plurality of bit lines BL.

In a memory device having a cell over periphery (COP) structure, different voltages may be applied between the even and odd bit lines to perform a stress test. In contrast, in the memory device having the B-VNAND structure in which the first semiconductor layer L1 and the second semiconductor layer L2 are coupled to each other using the upper bonding pad TBM and the lower bonding pad BBM, the order in which the bit lines are disposed and the order in which the bonding pads PAD are disposed do not match due to a difference between a pitch of the bit lines and a pitch of the upper bonding pads TBM and the lower bonding pads BBM (e.g., 24 times the pitch of the bit lines). For this reason, with the related method of applying different voltages between even and odd bit lines, it may be possible to perform stress tests between a plurality of bit lines BL in the memory device having a B-VNAND structure, but it is not possible to perform the stress test between a plurality of bonding pads PAD. A detailed structure of the page buffer circuit for solving this problem will be described in detail with reference to FIGS. 7 to 15.

FIG. 7 is a plan view illustrating a page buffer circuit 121.

Referring to FIG. 7, the first semiconductor layer L1 may include the plurality of bit lines BL extending in the first direction Y. The plurality of bit lines BL may extend in the first direction Y and be disposed adjacent to each other at a spacing in the second direction X intersecting the first direction Y.

The plurality of bit lines BL may be implemented as the first upper metal layer M1. The second semiconductor layer L2 may include the page buffer circuit 121, and a lower metal layer LM extending in the first direction Y may be disposed above the page buffer circuit 121. The second semiconductor layer L2 may further include at least one metal layer disposed above the lower metal layer LM and/or at least one metal layer disposed below the lower metal layer LM. For example, the second semiconductor layer L2 may include three or more lower metal layers disposed along the vertical direction Z. Throughout the description, the “metal layer” may refer to a “conductive layer” and may not be limited to a metal material.

The page buffer circuit 121 may include a first page buffer column 121a, a second page buffer column 121b, a third page buffer column 121c, and a fourth page buffer column 121d sequentially adjacent to each other in the second direction X. The first page buffer column 121a may include first to sixth page buffers PB0 to PB5 disposed along the first direction Y. The second page buffer column 121b may include seventh to twelfth page buffers PB6 to PB11 disposed along the first direction Y. The third page buffer column 121c may include thirteenth to eighteenth page buffers PB12 to PB17 disposed along the first direction Y. The fourth page buffer column 121d may include nineteenth to twenty-fourth page buffers PB18 to PB23 disposed along the first direction Y. Thus, each of the page buffer columns 121a, 121b, 121c, and 121d may have a six-stage structure.

First to sixth bit lines BL0 to BL5 extending in the first direction Y and sequentially spaced apart and adjacent to each other in the second direction X may be disposed on an upper portion of the first page buffer column 121a. The first page buffer column 121a may have the first width WD1 in the second direction X, and the first width WD1 may correspond to a pitch of the first to sixth bit lines BL0 to BL5. Each of the first to sixth page buffers PB0 to PB5 may be connected to each of the first to sixth bit lines BL0 to BL5.

Seventh to twelfth bit lines BL6 to BL11 extending in the first direction Y and sequentially spaced apart and adjacent to each other in the second direction X may be disposed on an upper portion of the second page buffer column 121b. That is, the second page buffer column 121b may have the first width WD1 in the second direction X, and the first width WD1 may correspond to a pitch of the seventh to twelfth bit lines BL6 to BL11. Each of the seventh to twelfth page buffers PB6 to PB11 may be connected to each of the seventh to twelfth bit lines BL6 to BL11. The first and second page buffer columns 121a and 121b (or, a high voltage region of the page buffer) may have a second width WD2 in the second direction X, and the second width WD2 may correspond to twice the first width WD1. For example, the second width WD2 may correspond to a pitch of the first to twelfth bit lines BL0 to BL11.

Thirteenth to eighteenth bit lines BL12 to BL17 extending in the first direction Y and sequentially spaced apart and adjacent to each other in the second direction X may be disposed on an upper portion of the third page buffer column 121c. That is, the third page buffer column 121c may have the first width WD1 in the second direction X, and the first width WD1 may correspond to a pitch of the thirteenth to eighteenth bit lines BL12 to BL17. Each of the thirteenth to eighteenth page buffers PB12 to PB17 may be connected to each of the thirteenth to eighteenth bit lines BL12 to BL17.

Nineteenth to twenty-fourth bit lines BL18 to BL23 extending in the first direction Y and sequentially spaced apart and adjacent to each other in the second direction X may be disposed on an upper portion of the fourth page buffer column 121d. That is, the fourth page buffer column 121d may have the first width WD1 in the second direction X, and the first width WD1 may correspond to a pitch of the nineteenth to twenty-fourth bit lines BL18 to BL23. Each of the nineteenth to twenty-fourth page buffers PB18 to PB23 may be connected to each of the nineteenth to twenty-fourth bit lines BL18 to BL23.

The third and fourth page buffer columns 121c and 121d may have the second width WD2 in the second direction X, and the second width WD2 may correspond to twice the first width WD1. For example, the second width WD2 may correspond to a pitch of the thirteenth to twenty-fourth bit lines BL12 to BL23.

The plurality of bonding pads PAD may be spaced apart from each other and disposed adjacent to each other in the first direction Y. The plurality of bonding pads PAD extending in the second direction X may be formed and connected to one page buffer (or, to a high voltage transistor in the page buffer) and one bit line. That is, one page buffer may be connected to one bit line via one bonding pad, and, throughout the description, if the same number is assigned to each of the page buffer, the bonding pad, and the bit line, it may indicate that these components are connected to each other unless otherwise stated. For example, the first page buffer PB0 may be connected to the first bit line BL0 via the first bonding pad PAD0.

The plurality of bonding pads PAD may be disposed at any position in the second direction X, and may be formed with any width. For example, the plurality of bonding pads PAD may be disposed on the upper portions of the second and third page buffer columns 121b and 121c, and may be formed with the second width WD2.

The pitch of the plurality of bonding pads PAD may correspond to the pitch of the first to twenty-fourth bit lines BL0 to BL23. For example, a third width WD3 may correspond to the pitch of each of the plurality of bonding pads PAD.

In sum, the page buffer columns 121a, 121b, 121c, and 121d (or, a low voltage region of the page buffer) may have a width corresponding to the pitch of the first number of bit lines in the second direction X, the first and second page buffer columns 121a and 121b or the third and fourth page buffer columns 121c and 121d (or, the high voltage region of the page buffer circuit 121) may have a width corresponding to the pitch of the second number of bit lines in the second direction X, and the plurality of bonding pads PAD may have a width corresponding to the pitch of the third number of bit lines in the second direction X. In this case, the third number may be greater than the second number, and the second number may be greater than the first number.

Bit lines disposed at positions not corresponding to the positions of the plurality of bonding pads PAD in the second direction X may be connected to the corresponding bonding pads with separate wiring. In an example, the separate wiring connected to the bonding pad may be formed on the second upper metal layer M2 of FIG. 5. For example, the first bit line BL0 may be connected to the first bonding pad PAD0 through a wiring M2_w0 formed in the second upper metal layer M2. Likewise, the second bit line BL1, the nineteenth bit line BL18, and the twentieth bit line BL19 may be connected to a second bonding pad PAD1, a nineteenth bonding pad PAD18, and a twentieth bonding pad PAD19 through wirings M2_w1, M2_w18, and M2_w19 formed in the second upper metal layer M2, respectively.

FIG. 8A is a plan view illustrating the page buffer circuit 121 of FIG. 7 in more detail.

Referring to FIGS. 7 and 8A, a plurality of bonding pads PAD of FIG. 7 may be disposed on an upper portion (upper portion in the Z axis) at a position corresponding to the high voltage region HV of the page buffer circuit 121.

A first stage STAGE1 may include a first low voltage region LV0, a seventh low voltage region LV6, a thirteenth low voltage region LV12, and a nineteenth low voltage region LV18, and include a first high voltage region HV0, a seventh high voltage region HV6, a thirteenth high voltage region HV12, and a nineteenth high voltage region HV18. A plurality of high voltage transistors may be disposed in the high voltage regions, and a plurality of low voltage transistors may be disposed in the low voltage regions.

Each of the low voltage regions LV0, LV6, LV12, and LV18 of the first stage STAGE1 may have the first width WD1 in the second direction X and be adjacent to each other in the second direction X. The low voltage regions LV0, LV6, LV12, and LV18 may be separated from each other by a device isolation layer such as a shallow trench isolation (STI).

The high voltage regions HV0, HV6, HV12, and HV18 of the first stage STAGE1 may have the second width WD2 in the second direction X and may be adjacent to the low voltage regions LV0, LV6, LV12, and LV18 in the first direction Y. For example, the high voltage regions HV0, HV6, HV12, and HV18 may be separated from the low voltage regions LV0, LV6, LV12, and LV18 by a device isolation film.

The first low voltage region LV0 and at least a portion of the first and seventh high voltage regions HV0 and HV6 of the first stage STAGE1 may form the first page buffer PB0 of the first page buffer column 121a, and the seventh low voltage region LV6 and the remainder of the first and seventh high voltage regions HV0 and HV6 may form the seventh page buffer PB6 of the second page buffer column 121b. Likewise, the thirteenth low voltage region LV12 and at least a portion of the thirteenth and nineteenth high voltage regions HV12 and HV18 may form the thirteenth page buffer PB12 of the third page buffer column 121c, and the nineteenth low voltage region LV18 and the remainder of the thirteenth and nineteenth high voltage regions HV12 and HV18 may form the nineteenth page buffer PB18 of the fourth page buffer column 121d. Each of the page buffers PB0, PB6, PB12, and PB18 of the first stage STAGE1 may include one low voltage region and one high voltage region. For example, the seventh page buffer PB6 may include the seventh low voltage region LV6 and the seventh high voltage region HV6.

A second stage STAGE2 may include eighth and twentieth high voltage regions HV7 and HV19 adjacent to the seventh and nineteenth high voltage regions HV6 and HV18 of the first stage STAGE1 in the first direction Y, and second and fourteenth high voltage regions HV1 and HV13 adjacent to the eighth and twentieth high voltage regions HV7 and HV19 in the first direction Y. In addition, the second stage STAGE2 may include low voltage regions LV1, LV7, LV13, and LV19 adjacent to the second and fourteenth high voltage regions HV1 and HV13 in the first direction Y and adjacent to each other in the second direction X. As described above, the second stage STAGE2 may have a reflected configuration of the first stage STAGE1 in the Y-axis direction. In other words, the second stage STAGE2 may have a linearly symmetrical structure with respect to the first stage STAGE1.

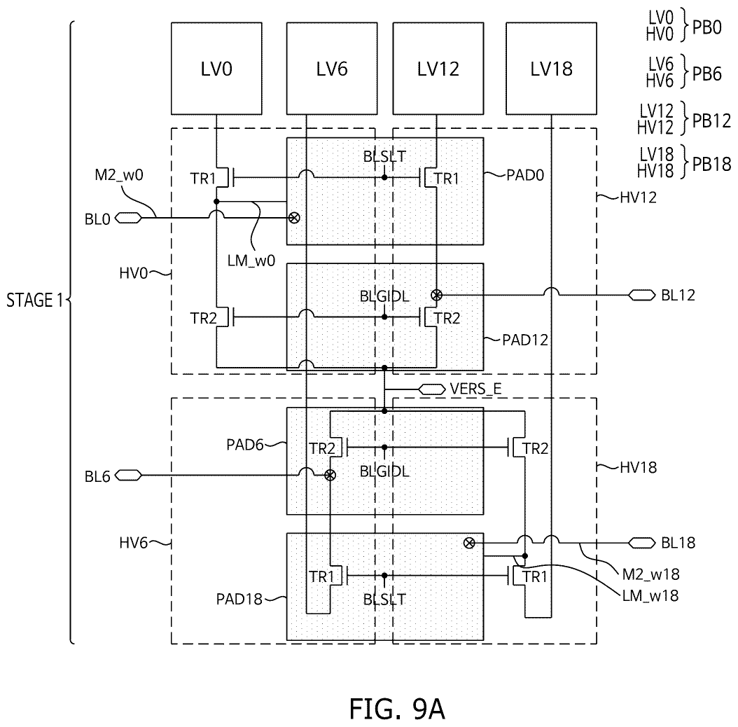

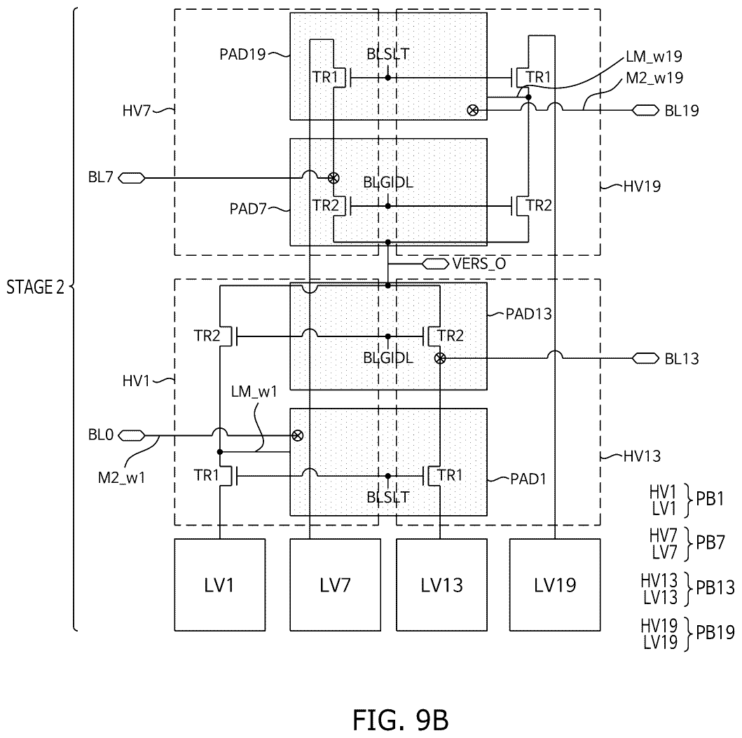

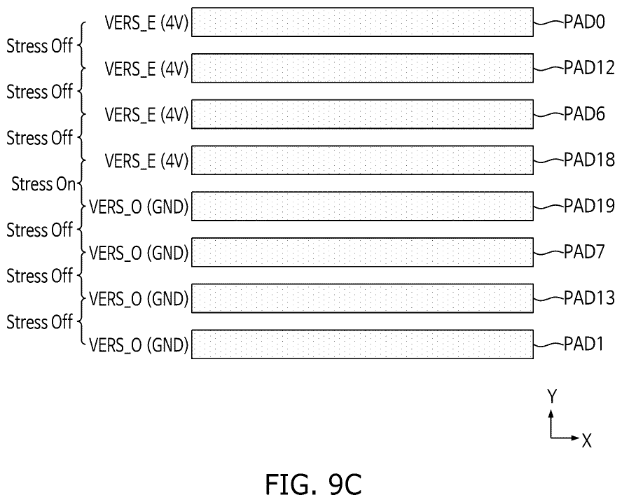

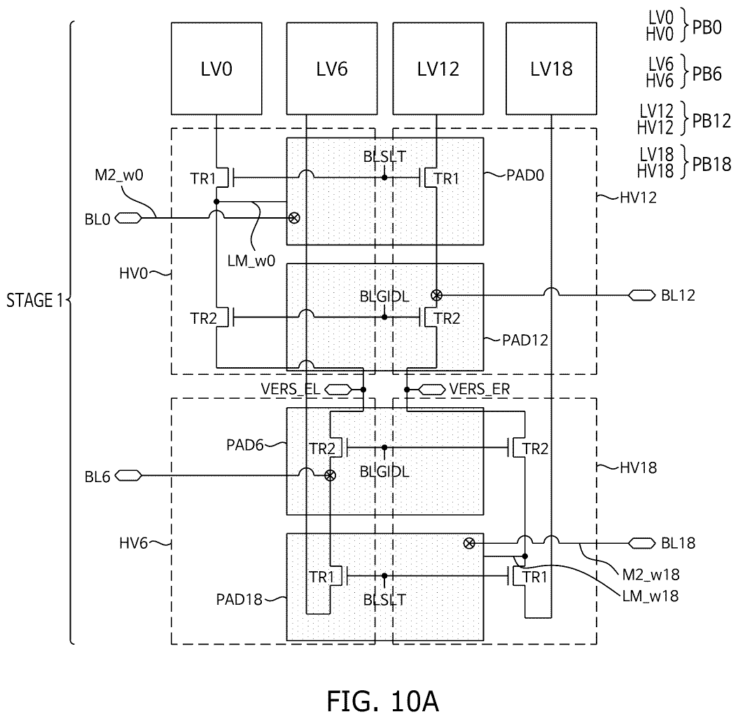

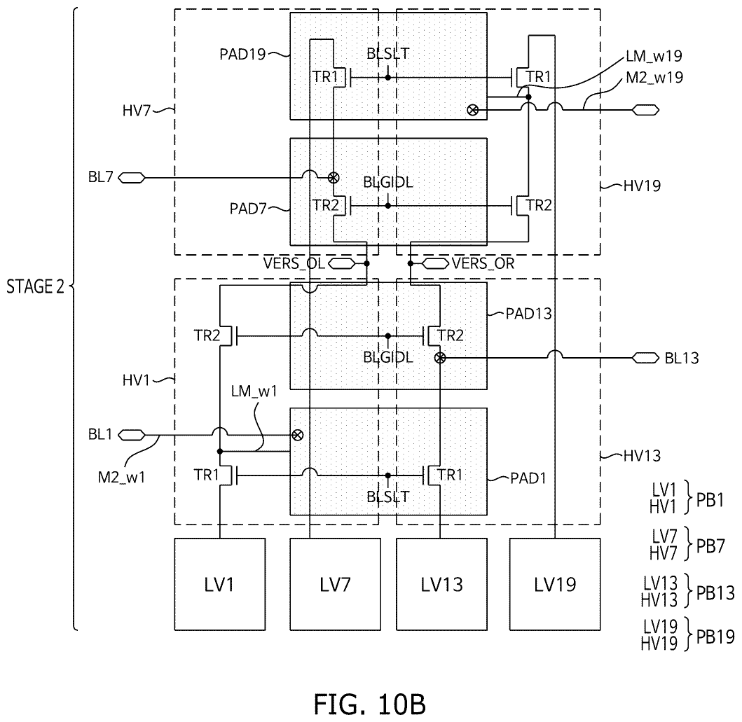

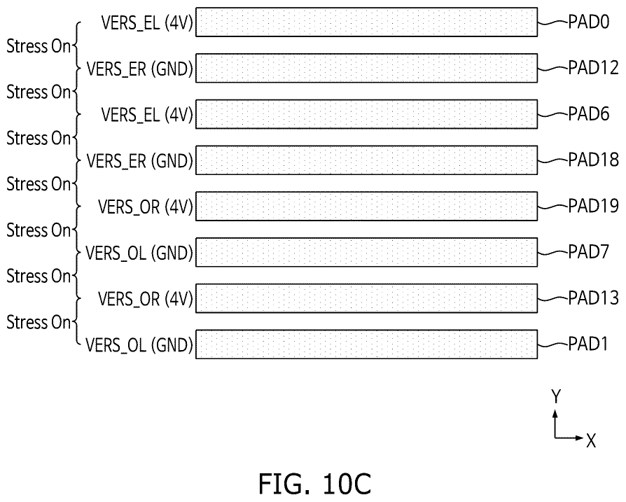

A third stage STAGE3 and a fourth stage STAGE4 may have the same structure and arrangement as those of the first stage STAGE1 and the second stage STAGE2. Likewise, a fifth stage STAGE5 and a sixth stage STAGE6 may have the same structure and arrangement as those of the first stage STAGE1 and the second stage STAGE2. The first to sixth stages STAGE1 to STAGE6 may be adjacent in pairs, and the adjacent pairs may have reflected configurations in the Y-axis direction. Aspects to be described below with reference to FIGS. 9A to 10C are mainly described with reference to the first stage STAGE1 and the second stage STAGE2, but the aspects may be equally applicable to the third stage STAGE3 and the fourth stage STAGE4, and a fifth stage STAGE5 and the sixth stage STAGE6.

FIG. 8B is a plan view illustrating a modification of the page buffer circuit 121 of FIG. 8A. First to sixth stages STAGE1 to STAGE6 of a page buffer circuit 121′ of FIG. 8B correspond to the first to sixth stages STAGE1 to STAGE6 of the page buffer circuit 121 of FIG. 8A, and may have an inverted configuration of each of the first to sixth stages STAGE1 to STAGE6 of the page buffer circuit 121 of FIG. 8 in the Y-axis direction.

If the page buffer circuit 121′ of FIG. 8B is applied, the arrangement of the bonding pad PAD of FIG. 7 may be changed to a position corresponding to the high voltage region HV of the page buffer circuit 121′.

FIG. 9A is a plan view illustrating in detail a high voltage region of the first stage STAGE1 of FIG. 8A, FIG. 9B is a plan view illustrating in detail a high voltage region of the second stage STAGE2 of FIG. 8A, and FIG. 9C is a diagram illustrating voltages applied to a plurality of bonding pads during a stress test using the high voltage circuits of FIGS. 9A and 9B.

Referring to FIG. 9A, the high voltage regions HV0, HV6, HV12, and HV18 of the first stage STAGE1 may include a high voltage transistor TR1, such as a bit line select transistor TR1, which is connected between the bit lines BL0, BL6, BL12, and BL18 and transistors of the low voltage regions LV0, LV6, LV12, and LV18 and driven by a bit line select signal BLSLT. In addition, each of the high voltage regions HV0, HV6, HV12, and HV18 may further include a high voltage transistor, i.e., an erase transistor TR2, which is connected between each of the bit lines BL0, BL6, BL12, and BL18 and an erase voltage line VERS_E and driven by an erase control signal BLGIDL. For example, the high voltage transistors TR1 and TR2 may operate in a high voltage region of about 2 V to about 28 V.

Gate terminals of the bit line select transistor TR1 of each of the high voltage regions disposed adjacent to each other in the second direction X may be connected to the same voltage source. Likewise, gate terminals of the erase transistor TR2 in each of the high voltage regions disposed adjacent to each other in the second direction X may be connected to the same voltage source. That is, the bit line select transistor TR1 and the erase transistor TR2 of each of the high voltage regions disposed adjacent to each other in the second direction X may be driven by the same bit line select signal BLSLT and erase control signal BLGIDL, respectively. Alternatively, the gate terminal of the bit line select transistor TR1 and/or the gate terminal of the erase transistor TR2 may be connected to a separate voltage source in each of the high voltage regions HV0, HV6, HV12, and HV18.

The erase transistor TR2 of each of the high voltage regions HV0, HV6, HV12, and HV18 may be connected to each of the bit lines BL0, BL6, BL12, and BL18 via each of the bonding pads PAD0, PAD6, PAD12, and PAD18. That is, the same voltage may be applied to any one of the bonding pads PAD0, PAD6, PAD12, and PAD18 and any one of the bit lines BL0, BL6, BL12, and BL18 corresponding thereto, and to the erase transistor TR2.

The erase transistor TR2 disposed at a position not corresponding to the positions of the bonding pads PAD0, PAD6, PAD12, and PAD18 in the second direction X may be connected to the bonding pad using a separate wiring. The separate wiring may be formed by using the lower metal layers LM0 to LM5 of FIG. 5. For example, the erase transistor TR2 in the first high voltage region HV0 may be connected to the first bonding pad PAD0 via a position corresponding to the first bonding pad PAD0 in the second direction X through a wiring LM_w0 formed in the lower metal layers LM0 to LM5. Likewise, the erase transistor TR2 of the nineteenth high voltage region HV18 may be connected to the nineteenth bonding pad PAD18 via a position corresponding to the nineteenth bonding pad PAD18 in the second direction X through a wiring LM_w18 formed in the lower metal layers LM0 to LM5.

Referring to FIG. 9B, the high voltage regions HV1, HV7, HV13, and HV19 of the second stage STAGE2 may include a high voltage transistor TR1, such as a bit line select transistor TR1, which is connected between the bit lines BL1, BL7, BL13, and BL19 and transistors of the low voltage regions LV1, LV7, LV13, and LV19 and driven by a bit line select signal BLSLT. In addition, each of the high voltage regions HV1, HV7, HV13, and HV19 may further include a high voltage transistor, i.e., an erase transistor TR2, which is connected between each of the bit lines BL1, BL7, BL13, and BL19 and an erase voltage line VERS_O and driven by an erase control signal BLGIDL. For example, the high voltage transistors TR1 and TR2 may operate in a high voltage region of about 2 V to about 28 V. The erase voltage line VERS_O connected to the erase transistor TR2 in the high voltage regions HV1, HV7, HV13, and HV19 of FIG. 9B may be different from the erase voltage line VERS_E connected to the erase transistor TR2 in the high voltage regions HV0, HV6, HV12, and HV18 of FIG. 9A.

The gate terminals of the bit line select transistor TR1 of each of the high voltage regions disposed adjacent to each other in the second direction X may be connected to the same voltage source. Likewise, the gate terminals of the erase transistor TR2 in each of the high voltage regions disposed adjacent to each other in the second direction X may be connected to the same voltage source. That is, the bit line select transistor TR1 and the erase transistor TR2 of each of the high voltage regions disposed adjacent to each other in the second direction X may be driven by the same bit line select signal BLSLT and the same erase control signal BLGIDL, respectively. Alternatively, the gate terminal of the bit line select transistor TR1 and/or the gate terminal of the erase transistor TR2 may be connected to a separate voltage source in each of the high voltage regions HV1, HV7, HV13, and HV19.

The erase transistor TR2 of each of the high voltage regions HV1, HV7, HV13, and HV19 may be connected to each of the bit lines BL1, BL7, BL13, and BL19 via each of the bonding pads PAD1, PAD7, PAD13, and PAD19. That is, the same voltage may be applied to any one of the bonding pads PAD1, PAD7, PAD13, and PAD19 and to any one of the bit lines BL1, BL7, BL13, and BL19 corresponding thereto, and to the erase transistor TR2.

The erase transistor TR2 disposed at a position not corresponding to the positions of the bonding pads PAD1, PAD7, PAD13, and PAD19 in the second direction X may be connected to the bonding pad using a separate wiring. The separate wiring may be formed by using the lower metal layers LM0 to LM5 of FIG. 5. For example, the erase transistor TR2 in the second high voltage region HV1 may be connected to the second bonding pad PAD1 via a position corresponding to the second bonding pad PAD1 in the second direction X through a wiring LM_w1 formed in the lower metal layers LM0 to LM5. Likewise, the erase transistor TR2 of the twentieth high voltage region HV19 may be connected to the twentieth bonding pad PAD19 via a position corresponding to the twentieth bonding pad PAD19 in the second direction X through a wiring LM_w19 formed in the lower metal layers LM0 to LM5.

Referring to FIGS. 9A and 9B, each of the low voltage regions LV0, LV1, LV6, LV7, LV12, LV13, LV18, and LV19 may be spaced apart from each of the corresponding high voltage regions HV0, HV1, HV6, HV7, HV12, HV13, HV18, and HV19 in the first direction Y and include a transistor connected to the erase transistor TR2 via the bit line select transistor TR1. For example, each of the low voltage regions LV0, LV1, LV6, LV7, LV12, LV13, LV18, and LV19 may include a transistor, such as a bit line shut-off transistor, which is connected between a sensing node and the high voltage transistor TR1 and driven by a bit line shut-off signal.

In addition, each of the low voltage regions LV0, LV1, LV6, LV7, LV12, LV13, LV18, and LV19 may further include a plurality of latches connected to the sensing node. For example, the plurality of latches may include a sensing latch, a force latch, an upper bit latch, a lower bit latch, or a cache latch, etc. Furthermore, each of the low voltage regions LV0, LV1, LV6, LV7, LV12, LV13, LV18, and LV19 may further include a precharge circuit capable of controlling a precharge operation for the bit line BL or the sensing node.

In response to activation of a mode for performing a stress test of a plurality of bit lines, a voltage applied to the erase transistor TR2 of the high voltage regions HV1, HV7, HV13, and HV19 of FIG. 9B and a voltage applied to the erase voltage line VERS_E connected to the erase transistor TR2 of the high voltage regions HV0, HV6, HV12, and HV18 of FIG. 9A may be set differently from each other. For example, if the structures of the first and second stages STAGE1 and STAGE2 described above are equally applied to the third and fourth stages STAGE3 and STAGE4, and to the fifth and sixth stages STAGE5 and STAGE6, a voltage of VERS_E (e.g., 4 V) may be applied to, among the bit lines BL0 to BL23 of FIG. 7, the bit lines (e.g., BL0, BL2, . . . , BL22) that are assigned even numbers (including zero (0)), and a voltage of VERS_O (e.g., a ground voltage) may be applied to the bit lines (e.g., BL1, BL3, . . . , BL23) assigned odd numbers. Accordingly, different voltages may be applied between adjacent bit lines, and the stress test may be performed on the bit lines BL0 to BL23.

Meanwhile, when performing a stress test on the plurality of bit lines BL, referring to FIG. 9C, a voltage (e.g., 4 V) of VERS_E may be applied to the bonding pads PAD0, PAD6, PAD12, and PAD18 that are assigned even numbers (including zero (0)) and a voltage (e.g., a ground voltage) of VERS_O may be applied to the bonding pads PAD1, PAD7, PAD13, and PAD19 that are assigned odd numbers. With the bonding pads PAD0, PAD6, PAD12, and PAD18 assigned even numbers (including 0) being adjacent to each other, and the bonding pads PAD1, PAD7, PAD13, and PAD19 assigned odd numbers being adjacent to each other, stress may occur only between the nineteenth bonding pad PAD18 and the twentieth bonding pad PAD19 adjacent to each other (Stress On), and stress may not occur between the other adjacent bonding pads (Stress Off). That is, in the structures illustrated in FIGS. 9A and 9B, the stress test of the bit lines BL0 through BL23 may be performed, but the stress test between the bonding pads PAD of FIG. 7 may not be performed. Therefore, a high voltage region structure that allows both the stress test on the bit lines BL0 to BL23 and the stress test between the bonding pads PAD will be described below with reference to FIGS. 10A and 10B.

FIG. 10A is a plan view illustrating in detail the high voltage region of the first stage STAGE1 of FIG. 8A according to another aspect, FIG. 10B is a plan view illustrating in detail the high voltage region of the second stage STAGE2 of FIG. 8A, and FIG. 10C is a diagram illustrating voltages applied to the plurality of bonding pads during a stress test using the high voltage regions of FIGS. 10A and 10B.

Referring to FIG. 10A, the circuit of the high voltage regions HV0, HV6, HV12, and HV18 may be changed from FIG. 9A such that different erase voltage lines VERS_EL and VERS_ER are connected to each of the erase transistors TR2 of the high voltage regions adjacent to each other in the second direction X in the high voltage regions HV0, HV6, HV12, and HV18 of the first stage STAGE1. For example, a first erase voltage line VERS_EL may be connected to the erase transistor TR2 in the high voltage regions HV0 and HV6 illustrated on the left-hand side of FIG. 10A, and a second erase voltage line VERS_ER may be connected to the erase transistor TR2 in the high voltage regions HV12 and HV18 illustrated on the right-hand side of the drawing.

Referring to FIG. 10B, the circuit of the high voltage regions HV1, HV7, HV13, and HV19 may be changed from FIG. 9B such that different erase voltage lines VERS_OL and VERS_OR are connected to each of the erase transistors TR2 of the high voltage regions adjacent to each other in the second direction X in the high voltage regions HV1, HV7, HV13, and HV19 of the second stage STAGE2. For example, a third erase voltage line VERS_OL may be connected to the erase transistor TR2 in the high voltage regions HV1 and HV7 illustrated on the left-hand side of FIG. 10B, and a fourth erase voltage line VERS_OR may be connected to the erase transistor TR2 in the high voltage regions HV13 and HV19 illustrated on the right-hand side of the drawing.

Referring to FIGS. 10A and 10B, in response to activation of the first mode for performing a stress test on the plurality of bonding pads PAD, different voltages may be applied to the first erase voltage line VERS_EL and the second erase voltage line VERS_ER. Likewise, in response to activation of the first mode, different voltages may be applied to the third erase voltage line VERS_OL and the fourth erase voltage line VERS_OR.

For example, in response to activation of the first mode, a positive voltage (e.g., 4 V) may be applied to any one of the first erase voltage line VERS_EL and the second erase voltage line VERS_ER, and a ground voltage (GND) may be applied to the other one of the first erase voltage line VERS_EL and the second erase voltage line VERS_ER. Likewise, a positive voltage (e.g., 4 V) may be applied to any one of the third erase voltage line VERS_OL and the fourth erase voltage line VERS_OR, and a ground voltage may be applied to the other one of the third erase voltage line VERS_OL and the fourth erase voltage line VERS_OR.

Additionally, the voltage applied to the first erase voltage line VERS_EL and the voltage applied to the third erase voltage line VERS_OL may be different from each other, and the voltage applied to the second erase voltage line VERS_ER and the voltage applied to the fourth erase voltage line VERS_OR may be different from each other.

Additionally, the same voltage may be applied to the first erase voltage line VERS_EL and the fourth erase voltage line VERS_OR, and the same voltage may be applied to the second erase voltage line VERS_ER and the third erase voltage line VERS_OL.

In response to activation of a second mode for performing the erase operation on the memory cell connected to the bit lines BL0, BL6, BL12, and BL18 connected to the first stage STAGE1, the same voltage (e.g., erase voltage) may be applied to the first erase voltage line VERS_EL and the second erase voltage line VERS_ER. Likewise, in response to activation of the second mode for performing the erase operation on the memory cell connected to the bit lines BL1, BL7, BL13, and BL19 connected to the second stage STAGE2, the same voltage (e.g., erase voltage) may be applied to the third erase voltage line VERS_OL and the fourth erase voltage line VERS_OR. If the second mode is activated, the same voltage may be applied to the first erase voltage line VERS_EL, the second erase voltage line VERS_ER, the third erase voltage line VERS_OL, and the fourth erase voltage line VERS_OR.

In response to activation of a third mode for performing a stress test on the plurality of bit lines, different voltages may be applied to the first erase voltage line VERS_EL and the third erase voltage line VERS_OL, and different voltages may be applied to the second erase voltage line VERS_ER and the fourth erase voltage line VERS_OR. Additionally, the voltage applied to the first erase voltage line VERS_EL and the voltage applied to the second erase voltage line VERS_ER may be the same, and the voltage applied to the third erase voltage line VERS_OL and the voltage applied to the fourth erase voltage line VERS_OR may be the same as each other. In contrast, the voltage applied to the first erase voltage line VERS_EL and the voltage applied to the second erase voltage line VERS_ER may be different, and the voltage applied to the third erase voltage line VERS_OL and the voltage applied to the fourth erase voltage line VERS_OR may be different from each other. In this case, the third mode may be included in the first mode for performing the stress test on the plurality of bonding pads PAD. That is, in response to the activation of the first mode, the stress test between the plurality of bit lines BL and the stress test on the plurality of bonding pads PAD may be performed together.

Referring to FIG. 10C, when performing the stress test on the plurality of bonding pads PAD or the stress test on the plurality of bit lines BL, the voltage of VERS_E (e.g., 4 V) and the voltage of VERS_O (e.g., ground voltage) between adjacent bonding pads may be alternately applied, resulting in stress between the plurality of bonding pads PAD (Stress On). Therefore, it is possible to perform both the stress test on the bit lines BL0 to BL23 and the stress test between the bonding pads PAD.

FIG. 11 is a plan view illustrating a page buffer circuit 122.

Referring to FIG. 11, an aspect corresponding to a modification of the aspect illustrated in FIG. 7 will be described, and a redundant description thereof will be omitted. The page buffer circuit 122 may include a first page buffer column 122a, a second page buffer column 122b, a third page buffer column 122c, and a fourth page buffer column 122d sequentially adjacent to each other in the second direction X. The first page buffer column 122a may include first to fourth page buffers PB0 to PB3 disposed along the first direction Y. The second page buffer column 122b may include fifth to eighth page buffers PB4 to PB7 disposed along the first direction Y. The third page buffer column 122c may include ninth to twelfth page buffers PB8 to PB11 disposed along the first direction Y. The fourth page buffer column 122d may include thirteenth to sixteenth page buffers PB12 to PB15 disposed along the first direction Y. As described above, each of the first to fourth page buffer columns 122a, 122b, 122c, and 122d may have a four-stage structure.

First to fourth bit lines BL0 to BL3 extending in the first direction Y and sequentially spaced apart and adjacent to each other in the second direction X may be disposed on an upper portion of the first page buffer column 122a. The first page buffer column 122a may have a first width WD1′ in the second direction X, and the first width WD1′ may correspond to a pitch of the first to fourth bit lines BL0 to BL3. Each of the first to fourth page buffers PB0 to PB3 may be connected to each of the first to fourth bit lines BL0 to BL3.

Fifth to eighth bit lines BL4 to BL7 extending in the first direction Y and spaced apart from each other in the second direction X may be disposed on an upper portion of the second page buffer column 122b. That is, the second page buffer column 122b may have the first width WD1′ in the second direction X, and the first width WD1′ may correspond to a pitch of the fifth to eighth bit lines BL4 to BL7. Each of the fifth to eighth page buffers PB4 to PB7 may be connected to each of the fifth to eighth bit lines BL4 to BL7. The first and second page buffer columns 122a and 122b (or, the high voltage region of the page buffer) may have a second width WD2′ in the second direction X, and the second width WD2′ may correspond to twice the first width WD1′. For example, the second width WD2′ may correspond to a pitch of the first to eighth bit lines BL0 to BL7.

Ninth to twelfth bit lines BL8 to BL11 extending in the first direction Y and sequentially spaced apart and adjacent to each other in the second direction X may be disposed on an upper portion of the third page buffer column 122c. That is, the third page buffer column 122c may have the first width WD1′ in the second direction X, and the first width WD1′ may correspond to a pitch of the ninth to twelfth bit lines BL8 to BL11. Each of the ninth to twelfth page buffers PB8 to PB11 may be connected to each of the ninth to twelfth bit lines BL8 to BL11.

Thirteenth to sixteenth bit lines BL12 to BL15 extending in the first direction Y and sequentially spaced apart and adjacent to each other in the second direction X may be disposed on the fourth page buffer column 122d. That is, the fourth page buffer column 122d may have the first width WD1′ in the second direction X, and the first width WD1′ may correspond to a pitch of the thirteenth to sixteenth bit lines BL12 to BL15. Each of the thirteenth to sixteenth page buffers PB12 to PB15 may be connected to each of the thirteenth to sixteenth bit lines BL12 to BL15.

The third and fourth page buffer columns 122c and 122d may have the second width WD2′ in the second direction X, and the second width WD2′ may correspond to twice the first width WD1′. For example, the second width WD2′ may correspond to a pitch of the ninth to sixteenth bit lines BL8 to BL15.

The plurality of bonding pads PAD may be spaced apart from each other and disposed adjacent to each other in the first direction Y. The plurality of bonding pads PAD extending in the second direction X may be formed and connected to one page buffer (or, to a transistor in the page buffer) and one bit line. That is, one page buffer may be connected to one bit line via one bonding pad, and if the same number is assigned to each of the page buffer, the bonding pad, and the bit line, it may indicate that these components are connected to each other. For example, the first page buffer PB0 may be connected to the first bit line BL0 via the first bonding pad PAD0. If the positions of a specific page buffer and a bonding pad corresponding thereto do not match (or, do not correspond to each other) in the first direction Y, the specific page buffer and the corresponding bonding pad may be connected to each other using a separate wiring that is connected in a component direction including the first direction Y in the page buffer circuit 122. This will be described in detail below with reference to FIG. 12.

A plurality of bonding pads PAD may be disposed at any position in the second direction X, and may be formed with any width. For example, the plurality of bonding pads PAD may be disposed on the upper portions of the second and third page buffer columns 122b and 122c, and may be formed with the second width WD2′.

The pitch of the plurality of bonding pads PAD may correspond to the pitch of the first to sixteenth bit lines BL0 to BL15. For example, a third width WD3′ may correspond to the pitch of each of the plurality of bonding pads PAD.

In sum, the page buffer columns 122a, 122b, 122c, and 122d (or, the low voltage region of the page buffer) may have a width corresponding to the pitch of the first number of bit lines in the second direction X, the first and second page buffer columns 122a and 122b or the third and fourth page buffer columns 122c and 122d (or, the high voltage region of the page buffer circuit 122) may have a width corresponding to the pitch of the second number of bit lines in the second direction X, and the plurality of bonding pads PAD may have a width corresponding to the pitch of the third number of bit lines in the second direction X. In this case, the third number may be greater than the second number, and the second number may be greater than the first number.

Bit lines disposed at positions not corresponding to the positions of the plurality of bonding pads PAD in the second direction X may be connected to the corresponding bonding pads by separate wiring. The separate wiring connected to the bonding pad may be formed on the second upper metal layer M2 of FIG. 5. For example, the first bit line BL0 may be connected to the first bonding pad PAD0 through the wiring M2_w0 formed in the second upper metal layer M2. Likewise, the second bit line BL1, the thirteenth bit line BL12, and the fourteenth bit line BL13 may be connected to the second bonding pad PAD1, a thirteenth bonding pad PAD12, and a fourteenth bonding pad PAD13 through wirings M2_w1, M2_w12, and M2_w13 formed in the second upper metal layer M2, respectively.

FIG. 12 is a plan view illustrating in detail the page buffer circuit 122 of FIG. 11. Referring to FIGS. 11 and 12, a plurality of bonding pads PAD of FIG. 11 may be disposed on an upper portion (upper portion in the Z axis) at a position corresponding to the high voltage region HV of the page buffer circuit 122.

The first stage STAGE1 may include a first low voltage region LV0, a fifth low voltage region LV4, a ninth low voltage region LV8, and a thirteenth low voltage region LV12, and may include a first high voltage region HV0, a fifth high voltage region HV4, a ninth high voltage region HV8, and a thirteenth high voltage region HV12.

Each of the low voltage regions LV0, LV4, LV8, and LV12 of the first stage STAGE1 may have a first width WD1′ in the second direction X and may be adjacent to each other in the second direction X. The low voltage regions LV0, LV4, LV8, and LV12 may be separated from each other by a device isolation layer such as a shallow trench isolation (STI).

The high voltage regions HV0, HV4, HV8, and HV12 of the first stage STAGE1 may have a second width WD2′ in the second direction X and may be adjacent to the low voltage regions LV0, LV4, LV8, and LV12 in the first direction Y. For example, the high voltage regions HV0, HV4, HV8, and HV12 may be separated from the low voltage regions LV0, LV4, LV8, and LV12 by a device isolation layer.

The first low voltage region LV0 and at least a portion of the first and fifth high voltage regions HV0 and HV4 of the first stage STAGE1 may form the first page buffer PB0 of the first page buffer column 122a, and the fifth low voltage region LV4 and the remainder of the first and fifth high voltage regions HV0 and HV4 may form the fifth page buffer PB4 of the second page buffer column 122b. Likewise, the ninth low voltage region LV8 and at least a portion of the ninth and thirteenth high voltage regions HV8 and HV12 may form the ninth page buffer PB8 of the third page buffer column 122c, and the thirteenth low voltage region LV12 and the remainder of the ninth and thirteenth high voltage regions HV8 and HV12 may form the thirteenth page buffer PB12 of the fourth page buffer column 122d. Alternatively, each of the page buffers PB0, PB4, PB8, and PB12 of the first stage STAGE1 may include one low voltage region and one high voltage region. For example, the fifth page buffer PB4 may include the fifth low voltage region LV4 and the fifth high voltage region HV4.

The second stage STAGE2 may include sixth and fourteenth high voltage regions HV5 and HV13 adjacent to the fifth and thirteenth high voltage regions HV4 and HV12 of the first stage STAGE1 in the first direction Y, and second and tenth high voltage regions HV1 and HV9 adjacent to the sixth and fourteenth high voltage regions HV5 and HV13 in the first direction Y. The second stage STAGE2 may include low voltage regions LV1, LV5, LV9, and LV13 adjacent to each other in the second direction X. As described above, the second stage STAGE2 may have a reflected configuration of the first stage STAGE1 in the Y-axis direction. In other words, the second stage STAGE2 may have a linearly symmetrical structure with respect to the first stage STAGE1.

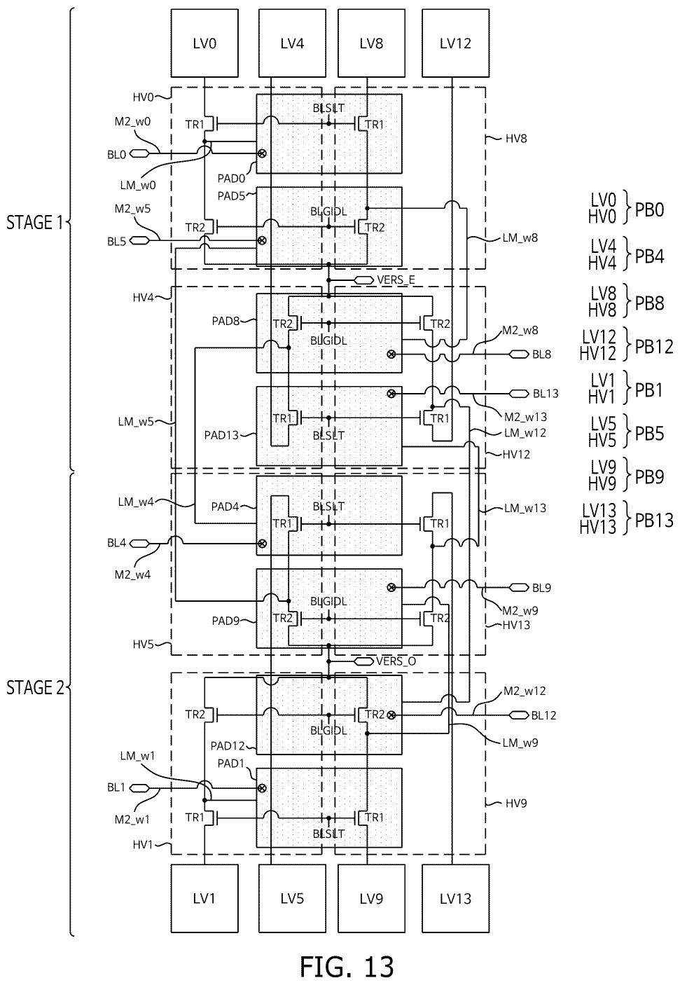

The third stage STAGE3 and the fourth stage STAGE4 may have the same structure and arrangement as those of the first stage STAGE1 and the second stage STAGE2. The first to fourth stages STAGE1 to STAGE4 may be adjacent in pairs, and the adjacent pairs may have reflected configurations in the Y-axis direction. Aspects to be described below with reference to FIGS. 13 to 15 are mainly described with reference to the first stage STAGE1 and the second stage STAGE2, but the aspects may be equally applicable to the third stage STAGE3 and the fourth stage STAGE4.

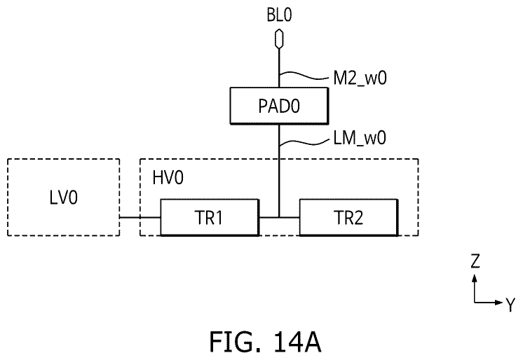

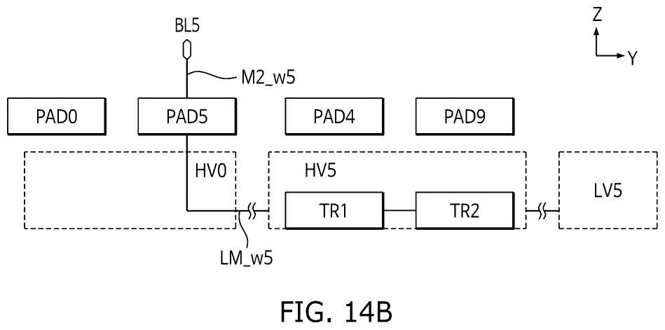

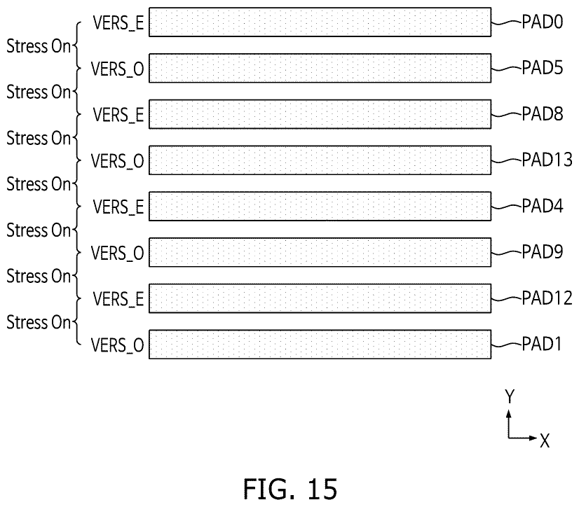

FIG. 13 is a plan view illustrating in detail the high voltage regions of the first and second stages STAGE1 and STAGE2 of FIG. 12, FIGS. 14A and 14B are diagrams illustrating in detail the connection structure of the bit lines BL0 and BL5 of FIG. 13, and FIG. 15 is a diagram illustrating voltages applied to the plurality of bonding pads according to the high voltage regions of FIG. 13.

Referring to FIG. 13, the high voltage regions HV0, HV4, HV8, and HV12 of the first stage STAGE1 may include a high voltage transistor TR1, such as the bit line select transistor TR1, which is connected between the bit lines BL0, BL4, BL8, and BL12 and the transistors of the low voltage regions LV0, LV4, LV8, and LV12 and driven by the bit line select signal BLSLT. In addition, each of the high voltage regions HV0, HV4, HV8, and HV12 of the first stage STAGE1 may further include a high voltage transistor, i.e., the erase transistor TR2, which is connected between each of the bit lines BL0, BL4, BL8, and BL12 and the first erase voltage line VERS_E and driven by the erase control signal BLGIDL. For example, the high voltage transistors TR1 and TR2 may operate in a high voltage region of about 2 V to about 28 V.

The high voltage regions HV1, HV5, HV9, and HV13 of the second stage STAGE2 may include a high voltage transistor TR1, such as the bit line select transistor TR1, which is connected between the bit lines BL1, BL5, BL9, and BL13 and the transistors of the low voltage regions LV1, LV5, LV9, and LV13 and driven by the bit line select signal BLSLT. In addition, each of the high voltage regions HV1, HV5, HV9, and HV13 may further include a high voltage transistor, i.e., the erase transistor TR2, which is connected between each of the bit lines BL1, BL5, BL9, and BL13 and the second erase voltage line VERS_O and driven by the erase control signal BLGIDL. The second erase voltage line VERS_O connected to the erase transistor TR2 in the high voltage regions HV1, HV5, HV9, and HV13 of the second stage STAGE2 may be different from the first erase voltage line VERS_E connected to the erase transistor TR2 of the high voltage regions HV0, HV4, HV8, and HV12 of the first stage STAGE1.

Each of the low voltage regions LV0, LV1, LV4, LV5, LV8, LV9, LV12, and LV13 may be spaced apart from each of the corresponding high voltage regions HV0, HV1, HV4, HV5, HV8, HV9, HV12, and HV13 in the first direction Y, and include a transistor connected to a corresponding erase transistor TR2 via the corresponding bit line select transistor TR1.

The gate terminal of the bit line select transistor TR1 of each of the high voltage regions disposed adjacent to each other in the second direction X may be connected to the same voltage source. That is, the bit line select transistor TR1 of each of the high voltage regions disposed adjacent to each other in the second direction X may be activated by the same bit line select signal. Likewise, the gate terminal of the erase transistor TR2 in each of the high voltage regions disposed adjacent to each other in the second direction X may be connected to the same voltage source. Alternatively, the gate terminal of the bit line select transistor TR1 and/or the gate terminal of the erase transistor TR2 may be connected to a separate voltage source in each of the high voltage regions HV0, HV4, HV8, and HV12 of the first stage STAGE1 and in each of the high voltage regions HV1, HV5, HV9, and HV13 of the second stage STAGE2.

The erase transistor TR2 of each of the high voltage regions HV0, HV4, HV8, and HV12 of the first stage STAGE1 may be connected to each of the bit lines BL0, BL4, BL8, and BL12 via each of the bonding pads PAD0, PAD4, PAD8, and PAD12. That is, the same voltage may be applied to each of the bonding pads PAD0, PAD4, PAD8, and PAD12 and each of the bit lines BL0, BL4, BL8, and BL12 corresponding thereto, and to the erase transistor TR2. The bonding pads PAD0, PAD4, PAD8, and PAD12 may be connected to the bit lines BL0, BL4, BL8, and BL12 through the wirings M2_w0, M2_w4, M2_w8, and M2_w12 formed in the second upper metal layer M2.

The erase transistor TR2 of each of the high voltage regions HV1, HV5, HV9, and HV13 of the second stage STAGE2 may be connected to each of the bit lines BL1, BL5, BL9, and BL13 via each of the bonding pads PAD1, PAD5, PAD9, and PAD13. That is, the same voltage may be applied to each of the bonding pads PAD1, PAD5, PAD9, and PAD13 and each of the bit lines BL1, BL5, BL9, and BL13 corresponding thereto, and to the erase transistor TR2. The bonding pads PAD1, PAD5, PAD9, and PAD13 may be connected to the bit lines BL1, BL5, BL9, and BL13 through the wirings M2_w1, M2_w5, M2_w9, and M2_w13 formed in the second upper metal layer M2.

In order to implement a page buffer circuit capable of performing both the stress test on the bit lines and the stress test between the bonding pads, a bonding pad connected to any one of the erase transistors TR2 connected with the first erase voltage line VERS_E may be spaced apart and disposed adjacent to a bonding pad connected to any one of the erase transistors TR2 connected to the second erase voltage line VERS_O, in the first direction Y.

In an example, referring to FIGS. 13 and 14A, the first bonding pad PAD0 connected to the first bit line BL0 may be connected to the erase transistor TR2 in the first high voltage region HV0 to which the first erase voltage line VERS_E is connected through the wiring LM_w0 formed in the lower metal layers LM0 to LM5, and may be disposed above the first high voltage region HV0 (in the Z direction).

Referring to FIGS. 13 and 14B, the sixth bonding pad PAD5 connected to the sixth bit line BL5 may be connected to the erase transistor TR2 of the sixth high voltage region HV5 to which the second erase voltage line VERS_O is connected through a wiring LM_w5 formed in the lower metal layers LM0 to LM5, and may be spaced apart and disposed adjacent to the first bonding pad PAD0 in the first direction Y above the first high voltage region HV0 (in the Z direction). The sixth bonding pad PAD5 and the second stage STAGE2 (or the high voltage regions HV1, HV5, HV9, and HV13 of the second stage STAGE2) may be spaced apart so as not to overlap each other in the first direction Y. That is, by adjusting the position of the sixth bonding pad PAD5 using the wiring LM_w5 formed on the lower metal layers LM0 to LM5, the bonding pads PAD0 and PAD5 connected to different erase voltage lines may be disposed to be adjacent to each other.

The erase transistor TR2 of the ninth high voltage region HV8 connected to the first erase voltage line VERS_E may be connected to the ninth bonding pad PAD8 above the first stage STAGE1 through a wiring LM_w8 formed in the lower metal layers LM0 to LM5. The erase transistor TR2 of the fourteenth high voltage region HV13 connected to the second erase voltage line VERS_O may be connected to the fourteenth bonding pad PAD13 above the first stage STAGE1 through a wiring LM_w13 formed in the lower metal layers LM0 to LM5. The ninth bonding pad PAD8 and the fourteenth bonding pad PAD13 may be spaced apart and disposed adjacent to each other in the first direction Y. The fourteenth bonding pad PAD13 and the high voltage regions HV1, HV5, HV9, and HV13 of the second stage STAGE2 may be spaced apart and disposed adjacent to each other so as not to overlap each other in the first direction Y. Additionally, the sixth bonding pad PAD5 and the ninth bonding pad PAD8 connected to the second erase voltage line VERS_O may be spaced apart and disposed adjacent to each other in the first direction Y.

The erase transistor TR2 of the tenth high voltage region HV9 connected to the second erase voltage line VERS_O may be connected to the tenth bonding pad PAD9 above the second stage STAGE2 through a wiring LM_w9 formed in the lower metal layers LM0 to LM5. The erase transistor TR2 in the fifth high voltage region HV4 connected to the first erase voltage line VERS_E may be connected to the fifth bonding pad PAD4 above the second stage STAGE2 through a wiring LM_w4 formed in the lower metal layers LM0 to LM5. The tenth bonding pad PAD9 and the fifth bonding pad PAD4 may be spaced apart and disposed adjacent to each other in the first direction Y. The fifth bonding pad PAD4 and the first stage STAGE1 (or the high voltage regions HV0, HV4, HV8, and HV12 of the first stage STAGE1) may be spaced apart and disposed adjacent to each other so as not to overlap each other in the first direction Y. Additionally, the fourteenth bonding pad PAD13 and the fifth bonding pad PAD4 connected to the second erase voltage line VERS_O may be spaced apart and disposed adjacent to each other in the first direction Y.

The erase transistor TR2 in the second high voltage region HV1 connected to the second erase voltage line VERS_O may be connected to the second bonding pad PAD1 above the second stage STAGE2 through the wiring LM_w1 formed in the lower metal layers LM0 to LM5. The erase transistor TR2 of the thirteenth high voltage region HV12 connected to the first erase voltage line VERS_E may be connected to the thirteenth bonding pad PAD12 above the second stage STAGE2 through a wiring LM_w12 formed in the lower metal layers LM0 to LM5. The second bonding pad PAD1 and the thirteenth bonding pad PAD12 may be spaced apart and disposed adjacent to each other in the first direction Y. The thirteenth bonding pad PAD12 and the first stage STAGE1 (or the high voltage regions HV0, HV4, HV8, and HV12 of the first stage STAGE1) may be disposed to be spaced apart from each other so as not to overlap each other in the first direction Y. Additionally, the tenth bonding pad PAD9 and the thirteenth bonding pad PAD12 connected to the second erase voltage line VERS_O may be spaced apart and disposed adjacent to each other in the first direction Y.

Referring to FIGS. 13 and 15, in response to activation of the first mode for performing the stress test on the plurality of bonding pads PAD and/or the stress test on the plurality of bit lines BL, a positive voltage (e.g., 4 V) may be applied to any one of the first erase voltage line VERS_E and the second erase voltage line VERS_O, and a ground voltage (GRD) may be applied to the other one of the first erase voltage line VERS_E and the second erase voltage line VERS_O.

For example, if the aspects of the first and second stages STAGE and STAGE2 described above are equally applied to the third and fourth stages STAGE3 and STAGE4 of FIG. 11, a voltage of VERS_E (e.g., 4 V) may be applied to, among the bit lines BL0 to BL15 of FIG. 11, the bit lines (e.g., BL0, BL2, . . . , BL14) that are assigned even numbers (including zero (0)), and a voltage of VERS_O (e.g., a ground voltage) may be applied to the bit lines (e.g., BL1, BL3, . . . , BL15) assigned with odd numbers. Accordingly, different voltages may be applied between adjacent bit lines, and the stress test on the bit lines BL0 to BL15 may be performed.

In addition, a voltage (e.g., 4 V) of the first erase voltage line VERS_E is applied to the bonding pads PAD0, PAD4, PAD8, and PAD12 assigned even numbers (including 0) of FIG. 15, a voltage (e.g., a ground voltage) of the second erase voltage line VERS_O is applied to the bonding pads PAD1, PAD5, PAD9, and PAD13 given odd numbers, and the bonding pads applied with voltages of different erase voltage lines are alternately disposed adjacent to each other. Accordingly, different voltages may be applied between adjacent bonding pads, and the stress test on the plurality of bonding pads PAD may be performed.

On the other hand, in response to activation of the second mode for performing the erase operation on the memory cells connected to the plurality of bit lines BL, the same voltage (e.g., erase voltage) may be applied to the first erase voltage line VERS_E and the second erase voltage line VERS_O.

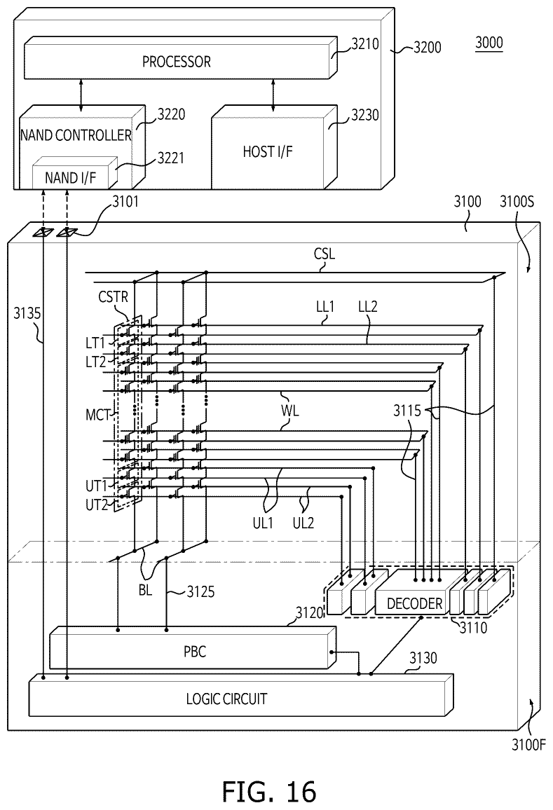

FIG. 16 is a block diagram illustrating an electronic system including a semiconductor device according to some aspects.

Referring to FIG. 16, an electronic system 3000 may include a semiconductor device 3100 and a controller 3200 electrically connected to the semiconductor device 3100. The electronic system 3000 may be a storage device including one or a plurality of semiconductor devices 3100 or an electronic device including the storage device. For example, the electronic system 3000 may be a solid state drive (SSD) device, a universal serial bus (USB), a computing system, a medical device, or a communication device including one or the plurality of semiconductor devices 3100.

For example, the semiconductor device 3100 may be a non-volatile memory device, for example, the non-volatile memory device described above with reference to FIGS. 1 to 15. The semiconductor device 3100 may include a first structure 3100F and a second structure 3100S on the first structure 3100F. The first structure 3100F may be a peripheral circuit structure including a decoder circuit 3110, a page buffer circuit 3120, and a logic circuit 3130. The second structure 3100S may be a memory cell structure including a bit line BL, a common source line CSL, word lines WL, first and second gate upper lines UL1 and UL2, first and second gate lower lines LL1 and LL2, and memory cell strings CSTR between the bit line BL and the common source line CSL.

In the second structure 3100S, each of the memory cell strings CSTR may include lower transistors LT1 and LT2 adjacent to the common source line CSL and upper transistors UT1 and UT2 adjacent to the bit line BL, and a plurality of memory cell transistors MCT disposed between the lower transistors LT1 and LT2 and the upper transistors UT1 and UT2. The number of the lower transistors LT1 and LT2 and the number of the upper transistors UT1 and UT2 may vary according to various aspects.

In some aspects, the upper transistors UT1 and UT2 may include a string select transistor, and the lower transistors LT1 and LT2 may include a ground select transistor. The lower gate lines LL1 and LL2 each may be gate electrodes of the lower transistors LT1 and LT2. The word lines WL may be gate electrodes of the memory cell transistors MCT, and the upper gate lines UL1 and UL2 may be gate electrodes of the upper transistors UT1 and UT2, respectively.

In some aspects, the lower transistors LT1 and LT2 may include a lower erase control transistor LT1 and a ground select transistor LT2 connected in series. The upper transistors UT1 and UT2 may include a string select transistor UT1 and an upper erase control transistor UT2 connected to each other in series. At least one of the lower erase control transistor LT1 and the upper erase control transistor UT1 may be used for the erase operation of erasing data stored in the memory cell transistors MCT using a gate induced leakage current (GIDL) phenomenon.

The common source line CSL, the first and second lower gate lines LL1 and LL2, the word lines WL, and the first and second upper gate lines UL and UL2 may be electrically connected to the decoder circuit 3110 through first connection wirings 3115 extending from within the first structure 3100F and to a second structure 1100S. The bit lines BL may be electrically connected to the page buffer circuit 3120 through second connection wirings 3125 extending from within the first structure 3100F and to the second structure 3100S.

In the first structure 3100F, a decoder circuit 1110 and the page buffer circuit 3120 may perform a control operation on at least one memory cell transistor selected from among the plurality of memory cell transistors MCT. The decoder circuit 3110 and the page buffer circuit 3120 may be controlled by the logic circuit 3130. The semiconductor device 3000 may communicate with the controller 3200 through an input and output pad 3101 electrically connected to the logic circuit 3130. The input and output pad 3101 may be electrically connected to the logic circuit 3130 through an input and output connection wiring 3135 extending from within the first structure 3100F and to the second structure 3100S.

The controller 3200 may include a processor 3210, a NAND controller 3220, and a host interface 3230. According to some aspects, the electronic system 3000 may include the plurality of semiconductor devices 3100, and in this case, the controller 3200 may control a plurality of semiconductor devices 3000.

The processor 3210 may control the overall operation of the electronic system 3000 including the controller 3200. The processor 3210 may operate according to predetermined firmware, and may control the NAND controller 3220 to access the semiconductor device 3100. The NAND controller 3220 may include a NAND interface 3221 that processes communication with the semiconductor device 3100. A control command for controlling the semiconductor device 3100, data to be written in the memory cell transistors MCT of a semiconductor device 3100, data to be read from the memory cell transistors MCT of the semiconductor device 3100, etc. may be transmitted through the NAND interface 3221. The host interface 3230 may provide a function of communication between the electronic system 3000 and an external host. Upon receiving a control command from the external host through the host interface 3230, in response to the control command, the processor 3210 may control the semiconductor device 3100.

While this disclosure contains many specific implementation details, these should not be construed as limitations on the scope of what may be claimed. Certain features that are described in this disclosure in the context of separate implementations can also be implemented in combination in a single implementation. Conversely, various features that are described in the context of a single implementation can also be implemented in multiple implementations separately or in any suitable subcombination. Moreover, although features may be described above as acting in certain combinations, one or more features from a combination can in some cases be excised from the combination, and the combination may be directed to a subcombination or variation of a subcombination.

The present disclosure is not limited to the aspects described above and the accompanying drawings, and various forms of substitution, modification, and change will be possible by those of ordinary skill in the art without departing from the technical idea of the present disclosure described in the claims, which also fall within the scope of the present disclosure.

1. A non-volatile memory device comprising:
a plurality of bit lines comprising a first bit line and a second bit line;
a page buffer circuit comprising:
a first page buffer comprising a first erase transistor connected to the first bit line via a first bonding pad, and
a second page buffer comprising a second erase transistor connected to the second bit line via a second bonding pad; and
a plurality of bonding pads comprising the first bonding pad and the second bonding pad,
wherein the page buffer circuit is connected to the plurality of bit lines via the plurality of bonding pads,
wherein the first erase transistor is configured to be driven based on a first erase control signal, the first erase transistor being connected between the first bit line and a first erase voltage line,
wherein the second erase transistor is configured to be driven based on the first erase control signal, the second erase transistor being connected between the second bit line and a second erase voltage line different from the first erase voltage line, and
wherein the first bonding pad and the second bonding pad are disposed adjacent to each other.

2. The non-volatile memory device according to claim 1, wherein the page buffer circuit is configured to, in response to activation of a first mode in which a stress test is performed on the plurality of bonding pads, apply different voltages to the first erase voltage line and the second erase voltage line.

3. The non-volatile memory device according to claim 2, wherein the page buffer circuit is configured to, in response to the activation of the first mode,
apply a positive voltage to one of the first erase voltage line or the second erase voltage line, and
apply a ground voltage to the other one of the first erase voltage line or the second erase voltage line.

4. The non-volatile memory device according to claim 1, wherein the page buffer circuit is configured to, in response to activation of a second mode in which an erase operation is performed on a memory cell connected to the first bit line and the second bit line, apply a same voltage to the first erase voltage line and the second erase voltage line.

5. The non-volatile memory device according to claim 1, wherein
the page buffer circuit has a multi-stage structure comprising a plurality of stages,
a first stage of the multi-stage structure comprises the first page buffer and the second page buffer,
a second stage adjacent to the first stage of the multi-stage structure comprises:
a third page buffer comprising a third erase transistor connected to a third bit line of the plurality of bit lines via a third bonding pad of the plurality of bonding pads, and
a fourth page buffer comprising a fourth erase transistor connected to a fourth bit line of the plurality of bit lines via a fourth bonding pad of the plurality of bonding pads,
the third erase transistor is configured to be driven based on a second erase control signal, the third erase transistor being connected between the third bit line and a third erase voltage line,
the fourth erase transistor is configured to be driven based on the second erase control signal, the fourth erase transistor being connected between the fourth bit line and a fourth erase voltage line different from the third erase voltage line,
the third bonding pad and the fourth bonding pad are disposed adjacent to each other, and
the fourth bonding pad and the second bonding pad are disposed adjacent to each other.

6. The non-volatile memory device according to claim 5, wherein the page buffer circuit is configured to, in response to activation of a first mode in which a stress test is performed on the plurality of bonding pads:
apply a first voltage to the first erase voltage line and a second voltage different from the first voltage to the second erase voltage line,
apply a third voltage to the third erase voltage line and a fourth voltage different from the third voltage to the fourth erase voltage line, and
wherein the second voltage applied to the second erase voltage line is different from the fourth voltage applied to the fourth erase voltage line.

7. The non-volatile memory device according to claim 6, wherein the page buffer circuit is configured to, in response to activation of the first mode in which the stress test is performed on the plurality of bonding pads:
apply the first voltage to the first erase voltage line and to the fourth erase voltage line, and
apply the second voltage to the second erase voltage line and to the third erase voltage line.

8. The non-volatile memory device according to claim 5, wherein
the first bit line and the third bit line are disposed adjacent to each other,
the second bit line and the fourth bit line are disposed adjacent to each other, and
the page buffer circuit is configured to, in response to an activation of a third mode in which a stress test is performed on the plurality of bit lines,
apply a first voltage to the first erase voltage line and a third voltage different from the first voltage to the third erase voltage line, and
apply a second voltage to the second erase voltage line and to the fourth erase voltage line.

9. The non-volatile memory device according to claim 1, wherein
the first bit line and the second bit line extend in a first direction and are spaced apart from each other, the first bit line being disposed adjacent to the second bit line in a second direction intersecting the first direction, and
the first bonding pad and the second bonding pad are spaced apart from each other and disposed adjacent to each other in the first direction.

10. The non-volatile memory device according to claim 1, wherein
the plurality of bonding pads comprises a plurality of upper bonding pads and a plurality of lower bonding pads,
the plurality of bit lines and the plurality of upper bonding pads are formed on a first semiconductor layer of the non-volatile memory device,
the plurality of lower bonding pads and the page buffer circuit are formed on a second semiconductor layer of the non-volatile memory device, and
the first semiconductor layer and the second semiconductor layer are coupled by bonding the plurality of upper bonding pads and the plurality of lower bonding pads.

11. The non-volatile memory device according to claim 1, wherein the first page buffer comprises:
a high voltage region comprising the first erase transistor and a bit line select transistor; and
a low voltage region spaced apart from the high voltage region in a first direction and comprising a transistor connected to the first erase transistor via the bit line select transistor.

12. The non-volatile memory device according to claim 11, wherein
the plurality of bit lines extend in the first direction and are disposed to be spaced apart from each other in a second direction intersecting the first direction,
the low voltage region has a width corresponding to a pitch of a first number of bit lines in the second direction,
the high voltage region has a width corresponding to a pitch of a second number of bit lines in the second direction,
the first bonding pad has a pitch corresponding to a pitch of a third number of bit lines in the second direction, and
the third number is greater than the second number and the second number is greater than the first number.

13. The non-volatile memory device according to claim 11, wherein the bit line select transistor is configured to be driven based on a bit line select signal, the bit line select transistor being connected between the first bit line and a transistor in the low voltage region.

14. A non-volatile memory device, comprising:
a plurality of bit lines comprising a first bit line and a second bit line;
a page buffer circuit comprising a first page buffer comprising a first erase transistor connected to the first bit line via a first bonding pad, and a second page buffer comprising a second erase transistor connected to the second bit line via a second bonding pad; and
a plurality of bonding pads comprising the first bonding pad and the second bonding pad, wherein the page buffer circuit is connected to the plurality of bit lines via the plurality of bonding pads, wherein
the first erase transistor is configured to be driven based on a first erase control signal, the first erase transistor being connected between the first bit line and a first erase voltage line,
the second erase transistor is configured to be driven based on the first erase control signal, the second erase transistor being connected between the second bit line and a second erase voltage line different from the first erase voltage line,
the first bonding pad and the second bonding pad are disposed adjacent to each other,
the page buffer circuit is configured to, in response to activation of a mode in which a stress test is performed on the plurality of bonding pads, apply a positive voltage to either of the first erase voltage line or the second erase voltage line, and apply a ground voltage to the other one of the first erase voltage line or the second erase voltage line,
the plurality of bonding pads comprises a plurality of upper bonding pads and a plurality of lower bonding pads,
the plurality of bit lines and the plurality of upper bonding pads are formed on a first semiconductor layer,
the plurality of lower bonding pads and the page buffer circuit are formed on a second semiconductor layer,
the first semiconductor layer and the second semiconductor layer are coupled by bonding the plurality of upper bonding pads and the plurality of lower bonding pads, and
the first page buffer comprises;
a high voltage region comprising the first erase transistor and a bit line select transistor; and
a low voltage region spaced apart from the high voltage region in a first direction and comprising a transistor connected to the first erase transistor via the bit line select transistor.

15. A non-volatile memory device, comprising:
a plurality of bit lines comprising a first bit line and a second bit line, and extending in a first direction, respectively;
a plurality of bonding pads; and
a page buffer circuit having a multi-stage structure comprising a plurality of stages, wherein the page buffer circuit comprises a plurality of page buffers and is connected to the plurality of bit lines via the plurality of bonding pads,
wherein a first stage of the multi-stage structure comprises a plurality of first high voltage regions comprising a plurality of first erase transistors connected to a first erase voltage line,
wherein a second stage of the multi-stage structure comprises a plurality of second high voltage regions comprising a plurality of second erase transistors connected to a second erase voltage line different from the first erase voltage line,
wherein a first transistor of the plurality of first erase transistors is connected between the first bit line and the first erase voltage line,
wherein a second transistor of the plurality of second erase transistors is connected between the second bit line and the second erase voltage line,
wherein the first bit line is connected to the first transistor through a first bonding pad of the plurality of bonding pads,
wherein the second bit line is connected to the second transistor through a second bonding pad of the plurality of bonding pads,
wherein the first bonding pad and the second bonding pad are spaced apart and adjacent to each other in the first direction, and
wherein the second bonding pad and the plurality of second high voltage regions are disposed to be spaced apart from each other in a second direction intersecting the first direction.

16. The non-volatile memory device according to claim 15, wherein
the plurality of bit lines further comprises a third bit line and a fourth bit line,
a third transistor of the plurality of first erase transistors is connected between the third bit line and the first erase voltage line,
a fourth transistor of the plurality of second erase transistors is connected between the fourth bit line and the second erase voltage line,
the third bit line is connected to the third transistor through a third bonding pad of the plurality of bonding pads,
the fourth bit line is connected to the fourth transistor through a fourth bonding pad of the plurality of bonding pads,
the third bonding pad and the fourth bonding pad are spaced apart and adjacent to each other in the first direction,
the second bonding pad and the third bonding pad are spaced apart and adjacent to each other in the first direction, and
the third bonding pad and the plurality of first high voltage regions are disposed to be spaced apart from each other in the second direction.

17. The non-volatile memory device according to claim 15, wherein,
the page buffer circuit is configured to, in response to activation of a first mode in which a stress test is performed on the plurality of bonding pads,
apply a positive voltage to either of the first erase voltage line or the second erase voltage line, and
apply a ground voltage to the other one of the first erase voltage line or the second erase voltage line.

18. The non-volatile memory device according to claim 15, wherein the page buffer circuit is configured to, in response to activation of a second mode in which an erase operation is performed on a memory cell connected to the first bit line and the second bit line, apply a same voltage to the first erase voltage line and the second erase voltage line.

19. The non-volatile memory device according to claim 15, wherein
the plurality of bonding pads comprises a plurality of upper bonding pads and a plurality of lower bonding pads,
the plurality of bit lines and the plurality of upper bonding pads are formed on a first semiconductor layer of the non-volatile memory device,
the plurality of lower bonding pads and the page buffer circuit are formed on a second semiconductor layer of the non-volatile memory device, and
the first semiconductor layer and the second semiconductor layer are coupled by bonding the plurality of upper bonding pads and the plurality of lower bonding pads.

20. The non-volatile memory device according to claim 15, wherein
each of the plurality of first high voltage regions and each of the plurality of second high voltage regions further comprises a bit line select transistor, and
the page buffer circuit comprises:
a plurality of first low voltage regions spaced apart from the plurality of first high voltage regions in the first direction and each of the plurality of first low voltage regions and each of the plurality of first high voltage regions comprises a transistor connected to the plurality of first erase transistors via the bit line select transistor; and
a plurality of second low voltage regions spaced apart from the plurality of second high voltage regions in the first direction and each of the plurality of first low voltage regions and each of the plurality of first high voltage regions comprises a transistor connected to the plurality of first erase transistors via the bit line select transistor.
